(19) United States
(12) Patent Application Publication
(10) Pub. No.: US 2026/0052945 A1
(43) Pub. Date: Feb. 19, 2026

(54) SUBSTRATE-TO-SUBSTRATE BONDING USING ELECTROSTATIC CHUCKS

(71) Applicant: Applied Materials, Inc., Santa Clara, CA (US)

(72) Inventors: Lei XUE, Santa Clara, CA (US); Leonard M. TEDESCHI, San Jose, CA (US); Vijay D. PARKHE, San Jose, CA (US); Onkara Swamy KORASIDDARAMAIAH, Santa Clara, CA (US); Kartik RAMASWAMY, San Jose, CA (US)

(21) Appl. No.: 18/807,199

(22) Filed: Aug. 16, 2024

(51) Int. Cl. H01L 21/683; H01L 23/00

(52) U.S. Cl. CPC H01L 21/6831; H01L 24/80; H01L 2224/80895; H01L 2224/80896

(57) ABSTRACT

Embodiments of the disclosure describe an apparatus including a first electrostatic chuck (ESC) disposed in a processing region includes one or more segments and a surface of each of the one or more segments of the first ESC defines a first chucking surface that is oriented in a first direction. A first chucking force causes a first substrate to be urged against the first chucking surface. A second ESC disposed in the processing region includes one or more segments and a surface of each of the one or more segments of the second ESC defines a second chucking surface that is oriented in a second direction that is opposite the first direction. A second chucking force causes a second substrate to be urged against the second chucking surface. An actuator is configured to position the first ESC relative to the second ESC.

### BACKGROUND

### Field

Embodiments described herein generally relate to systems and methods used in wafer/substrate bonding. More specifically, embodiments of the present disclosure relate to a method and apparatus for substrate-to-substrate bonding.

### Description of the Related Art

Substrate-to-substrate bonding is a technique utilized in semiconductor device manufacturing in which two substrates/wafers are joined together as a single composite structure. To form the single composite structure, the substrates/wafers are first precisely aligned and then bonded together by fusion, thermal compression, or an adhesive. Each of the mechanisms for bonding the substrates/wafers together has disadvantages.

For example, avoiding outgassing is difficult when using adhesives and the strength of the adhesive bond often degrades over time. Thermal compression can cause stresses, warping, and other damage to the substrates/wafers during the bonding process. Fusion requires the surfaces of the substrates/wafers to be clean, smooth, and flat in order to bond the surfaces without voids or weak spots and a high-temperature annealing process to strengthen the bond. Accordingly, bonding the substrates/wafers via fusion involves integration of planarization, cleaning, and alignment processes to prepare the substrates/wafers for mechanical and thermal processes to bond the prepared substrates/wafers. The number of processes needed for fusion bonding often results in quality/uniformity variations in the bonds of wafer/substrate pairs.

Accordingly, there is a need in the art for a desirable substrate-to-substrate bonding system and process that solves the problems described above.

### SUMMARY

To the accomplishment of the foregoing and related ends, the one or more aspects comprise the features hereinafter fully described and particularly pointed out in the claims. The following description and the appended drawings set forth in detail certain illustrative features of the one or more aspects. These features are indicative, however, of but a few of the various ways in which the principles of various aspects may be employed.

Embodiments of the disclosure describe an apparatus including a first electrostatic chuck (ESC) that includes one or more segments. The first ESC is disposed within a processing region of a processing chamber. A surface of each of the one or more segments of the first ESC defines a first chucking surface that is oriented in a first direction. Each of the one or more segments of the first ESC includes at least one first electrode. The at least one first electrode in each of the one or more segments of the first ESC is configured to receive a first DC bias. The first DC bias is configured to generate a first chucking force that causes a first substrate to be urged against the first chucking surface. A second ESC includes one or more segments. The second ESC is disposed within the processing region. A surface of each of the one or more segments of the second ESC defines a second chucking surface that is oriented in a second direction that is opposite the first direction. Each of the one or more segments of the second ESC includes at least one second electrode. The at least one second electrode in each of the one or more segments of the second ESC is configured to receive a second DC bias. The second DC bias is configured to generate a second chucking force that causes a second substrate to be urged against the second chucking surface. An actuator is configured to position the first ESC relative to the second ESC.

Embodiments of the present disclosure provide a method that includes chucking a first substrate to a first surface of a first electrostatic chuck (ESC) disposed within a processing chamber. The first surface is oriented in a first direction. A second substrate is chucked to a second surface of a second ESC disposed within the processing chamber. The second surface is oriented in a second direction that is opposite the first direction. The second substrate is actuated towards the first substrate. The second substrate is bonded to the first substrate.

Embodiments of the present disclosure provide a method that includes receiving a first DC bias by at least one first electrode of a first electrostatic chuck (ESC) disposed within in a processing chamber. A first substrate is immobilized on a surface of the first ESC based on the first DC bias. A second DC bias is received by at least one second electrode of a second ESC disposed within the processing chamber. A second substrate is immobilized on a surface of the second ESC based on the second DC bias. The second substrate and the second ESC are rotated so that the first substrate faces the second substrate.

### BRIEF DESCRIPTION OF THE DRAWINGS

So that the manner in which the above recited features of embodiments of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a schematic illustration of an exemplary integrated substrate bonding platform that can be used to perform a bonding process sequence, in accordance with certain embodiments of the present disclosure.

FIGS. 2A and 2B illustrate an example of substrates that can be used during a bonding process within a processing chamber, in accordance with certain embodiments of the present disclosure.

FIGS. 3A, 3B, 3C, and 3D are views of two substrates at different times during a substrate bonding process, in accordance with certain embodiments of the present disclosure.

FIGS. 4A, 4B, and 4C are schematic representations electrostatic chucks (ESCs) that each include multiple segments that can be used during a bonding process, in accordance with certain embodiments of the present disclosure.

FIGS. 5A, 5B, 50, 5D, 5E, 5F, and 5G illustrate examples of using electrostatic chucks (ESCs) to bow substrates during a bonding process, in accordance with certain embodiments of the present disclosure.

FIG. 6 is a process flow diagram illustrating a method for bonding substrates using electrostatic chucks (ESCs) during one or more portions of a bonding process sequence, in accordance with certain embodiments of the present disclosure.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments of the disclosure provided herein generally relate to systems and methods used in wafer or substrate bonding processes. More specifically, embodiments of the present disclosure relate to electrostatic chucks (ESCs) for substrate-to-substrate bonding. In some embodiments, in the process of bonding one substrate to another substrate, a first DC bias is applied to a first pair of electrodes of a first ESC disposed within a processing chamber to retain a first substrate (e.g., wafer) on the surface of the first ESC and a second DC bias is applied to a second pair of electrodes of a second ESC disposed within the processing chamber to retain a second substrate (e.g., wafer) on the surface of the second ESC. A surface of the first substrate retained on the first ESC and a surface of the second substrate retained on the second ESC are then brought into contact to perform the bonding process. Physical/environmental properties within the processing chamber are controlled in order to facilitate the substrate-to-substrate bonding process. For example, a pressure and gas composition within the processing region of the processing chamber is maintained at a relatively low pressure, such as a vacuum pressure, with a controlled gas mixture (e.g., inert gases).

### Integrated Substrate Bonding System Examples

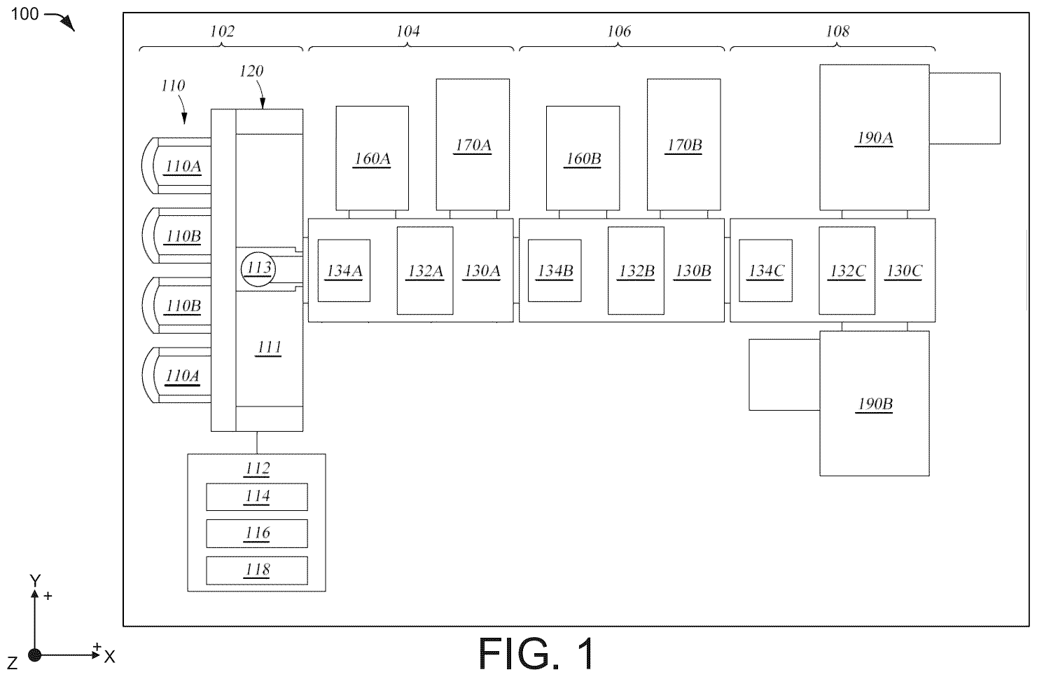

FIG. 1 is a schematic illustration of an exemplary integrated substrate bonding platform 100 that can be used to perform a bonding process sequence. The integrated substrate bonding platform 100 is configured to facilitate precise and efficient bonding of semiconductor devices through one or more automated processes. In some embodiments, the integrated substrate bonding platform 100 comprises an equipment front end module (EFEM) 102, surface preparation modules 104, 106, a bonding module 108, and a system controller 112. The EFEM 102 is configured to load and unload substrates from multiple substrate cassettes 110, and the surface preparation modules 104, 106 are configured to clean and activate substrates in preparation for bonding. The bonding module 108 is configured to execute a bonding process, which involves bonding source substrates 110A included in one or more front opening unified pods (FOUPs) to target substrates 110B included in one or more FOUPs. In some embodiments, the system controller 112 manages and coordinates operations of the various modules within the integrated substrate bonding platform 100.

The EFEM 102 comprises a support structure configured to accommodate a plurality of substrate cassettes 110 that are configured to retain source substrates 110A included in the one or more FOUPs and target substrates 110B included in the one or more FOUPs. The EFEM 102 further includes a housing 111 enclosing a chamber that provides a controlled environment for the handling and processing of the substrates. The enclosed chamber is configured to maintain cleanliness and integrity of the substrates during the bonding process by mitigating the risk of contamination and exposure to external factors. In addition, the EFEM 102 is equipped with one or more factory interface robots 113 that are operatively connected to the chamber and configured to transfer substrates between the substrate cassettes and various modules of the integrated substrate bonding platform 100. The factory interface robots 113 ensure precise and efficient movement of substrates through the system by automating substrate transfers, thereby contributing to the overall efficacy of the integrated bonding process.

The surface preparation module 104 is configured to perform a series of cleaning and activation steps on substrates, such as semiconductor wafers, using an integrated and automated system. In some embodiments, the surface preparation module 104 comprises an automated modular mainframe (AMM) 130A, a degas module 160A, and a plasma activation module 170A. The AMM 130A serves as the central hub of the system, coordinating the transfer of substrates between different sub-modules. This mainframe utilizes a substrate transfer robot that moves the substrates between various process stations, ensuring precise handling and minimizing the risk of contamination or damage.

The AMM 130A comprises a substrate aligner 132A and an in-line metrology system 134A. These components work in tandem to ensure proper substrate alignment and verification of surface characteristics before and after the surface preparation process. The substrate aligner 132A is configured to accurately align the substrates, ensuring that they are positioned precisely according to the requirements of the bonding process. The in-line metrology system 134A is configured to measure and verify the substrate surface characteristics, including cleanliness, activation level, and other relevant parameters, both before and after the cleaning and activation steps performed by the surface preparation module 104.

The degas module 160A is configured for outgassing the substrates by removing residual liquids, gases and contaminants that may have been adsorbed or trapped on the substrate surfaces during prior processing steps. This step is useful for ensuring that the substrate surface is free of contaminants that might interfere with subsequent processing steps, which include substrate bonding process steps.

The plasma activation module 170A is designed and configured for effective and efficient radical/plasma cleaning or activation processes. The plasma activation module 170A includes one or more radio frequency (RF) processing capabilities and/or a remote plasma source (RPS) that can be selectively positioned on the top, side wall, or any combination thereof of the chamber, providing flexibility in RPS placement. The RPS is further equipped with engineered hardware components, such as baffles and/or diffuser plates, which facilitate uniform distribution of gases or radicals within the chamber, thereby ensuring consistent process control and reproducibility. In one or more embodiments, the plasma activation module 170A is configured to operate in a variety of RPS/RF processes, including, but not limited to, RPS, RF plasma, RF-assisted RPS, RPS-assisted RF plasma, or intermittent RPS/RF processing. This versatility enables tailored cleaning or activation processes to be implemented, depending on the specific substrate materials and bonding applications being employed. The plasma activation module 170A is further configured to utilize a range of RPS/RF clean or activation gas chemistries, comprising, but not limited to, H₂, N₂, Ar, He, NH₃, NF₃, and clean dry air (CDA). Such compatibility with various gas chemistries allows the plasma activation module 170A to accommodate a multitude of substrate materials and surface conditions, thereby optimizing surface preparation for the integrated bonding process.

The surface preparation module 106 may include similar sub-modules as the surface preparation module 104 or alternative sub-modules as needed to address specific substrate cleaning and activation requirements. In some embodiments, the surface preparation module 106 includes an AMM 130B. As shown in FIG. 1, the AAM 130B comprises a substrate aligner 132B and an in-line metrology system 134B. Collectively, the surface preparation modules 104, 106 ensure that the source substrates 110A and target substrates 110B are thoroughly cleaned and activated, preparing them for the subsequent bonding process within the integrated substrate bonding platform 100.

The bonding module 108 is configured to execute the bonding of a source substrate 110A to a target substrate 110B, following the one or more surface preparation processes. The source substrate 110A and the target substrate 110B will typically include a plurality of dies or chiplets that are formed and/or aligned in a known pattern of the surfaces of the substrates. The bonding module 108 comprises an AMM 130C and a bonder module 190. The AMM 130C serves as the central control unit, managing and coordinating the operations of the bonder module 190 to ensure efficient and accurate substrate-to-substrate bonding. As will be discussed further below, the bonder module 190 performs the pick, rotation, placement, and bonding of the source substrate 110A to the target substrate 110B. With the use of a highly accurate robotic system, the bonder module 190 ensures precise alignment and positioning of dies (or chiplets) within the substrates throughout the integrated substrate bonding process. The bonder module 190 picks up the source substrate 110A, rotates the substrate to the correct position and orientation relative to the target substrate 110B, accurately places the source substrate 110A onto the target substrate 110B, and initiates the bonding process. In this configuration, the dies or chiplets formed within each of the substrates can be bonded together by the application of pressure, heat, electrostatic force, or combinations thereof. The terms substrate and wafer are utilized interchangeably throughout the disclosure provided herein to describe multiple die or chiplet containing work pieces on which one or more of the methods described herein are to be performed on.

A system controller 112, such as a programmable computer, is coupled to the integrated substrate bonding platform 100 for controlling one or more of the components therein. In some embodiments, the system controller 112 may control the substrate handling and transferring between different processing modules to perform a process sequence. In operation, the system controller 112 enables data acquisition and feedback from the respective components to coordinate processing in the integrated substrate bonding platform 100. The system controller 112 includes a programmable central processing unit (CPU) 114, which is operable with a memory 116 (e.g., non-volatile memory) and support circuits 118. The support circuits 118 (e.g., cache, clock circuits, input/output subsystems, power supplies, etc., and combinations thereof) are communicatively coupled to the CPU 114 and coupled to the various components within the integrated substrate bonding platform 100. Typically, the memory 116 is in the form of a non-transitory computer-readable storage media containing instructions (e.g., non-volatile memory), which when executed by the CPU 114, facilitates the operation of the integrated substrate bonding platform 100. The instructions in the memory 116 are in the form of a program product such as a program that implements the methods of the present disclosure. The program code may conform to any one of a number of different programming languages. In one example, the disclosure may be implemented as a program product stored on computer-readable storage media for use with a computer system. The program(s) of the program product define functions of the embodiments (including the methods described herein).

In operation, the integrated substrate bonding process flow begins by loading of source substrates 110A and target substrates 110B onto the EFEM 102 by one or more factory interface robots 113. The substrates 110A, 110B are then transported through the integrated substrate bonding platform 100 by the AMMs 130A, 130B. Next, the substrates 110A, 110B are aligned using the substrate aligners 132A, 132B to ensure accurate substrate-to-substrate and die-to-die placement during the bonding process. The aligned substrates 110A, 110B are transported to the degas modules 160A, 160B, where unwanted gases, moisture, or contaminants are removed from the surface of a substrate or a die containing work piece. The degas process typically involves heating the substrate or work piece to a specific temperature, causing the contaminants, trapped gases, or moisture to evaporate or desorb from the surface. In some cases, the process may also involve applying a vacuum or an inert gas to facilitate the removal of contaminants. Proper degassing can improve adhesion, reduce defects, and enhance the overall performance of the semiconductor device, particularly in the context of die-stack integrated bonding applications.

The degassed substrates 110A, 110B are then optionally treated in the plasma activation modules 170A, 170B for surface activation and further cleaning. During the plasma activation process, the surfaces of the dies/chiplets or substrates are exposed to plasma, which contains charged particles such as ions and electrons. High-energy ions bombard the surfaces of the dies/chiplets or substrates, removing contaminants and activating the surfaces by creating reactive sites that increase surface energy and wettability. This activation process makes the surface more hydrophilic and chemically reactive, promoting better adhesion and bonding quality in the integrated bonding process.

Finally, the substrates 110A, 110B are bonded using an integrated substrate bonding process performed by the bonder 190A or the bonder 190B. In the bonder module 190, the process of bonding source substrates 110A to target substrates 110B begins with the precise alignment of the dies on the source substrates 110A with the corresponding bonding sites on the target substrates 110B as described below. This alignment is achieved using advanced alignment systems, such as high-resolution cameras and pattern recognition algorithms, which accurately align interconnects, “street” regions, and/or surrounding dielectric material on the dies or substrates. Once the surface-to-surface and rotational angular alignment is achieved between the substrates, as will be discussed further below, the bonder module 190 will bring the source substrates 110A into contact with the target substrates 110B. In some embodiments, the mechanism for retaining the substrates during the bonding process may comprise electrostatic chucks, or in some cases vacuum-based gripping systems or other appropriate mechanisms suitable for handling substrates.

Prior to the actual bonding step, the bonder module 190 may apply a pre-bonding force to bring the surfaces of the source and target substrates 110A, 110B into intimate contact. This pre-bonding force ensures that interconnects and dielectric materials are in close proximity, which is useful for establishing reliable electrical connections and minimizing defects in the bonded structure. In some embodiments, the bonder module 190 then applies a controlled force and/or temperature to the source and target substrates 110A, 110B to initiate the bonding process. The forces and/or temperatures applied during the bonding process depend on the specific bonding technique being used, such as thermal compression bonding or direct bonding. In other embodiments, the bonder module 190 is configured to bond the source and target substrates 110A, 110B using pairs of substrate retaining elements, such as electrostatic chucks (ESC) which are described below. The bonding process may involve the formation of molecular bonds between the dielectric layers and the fusing of pads such as copper pads to establish electrical connections.

Throughout the bonding process, the bonder module 190 is equipped with sensors and feedback systems to monitor critical parameters, such as forces, temperatures, and alignment accuracy. This real-time monitoring enables fine-tuning and control of the substrate bonding process to ensure optimal bonding performance and yield. After the bonding process is completed, the bonded dies and substrates form a stacked semiconductor structure, with the source substrates 110A being bonded to the target substrates 110B. In some embodiments, the bonder module 190 then repeats this process where an additional substrate is bonded to the stacked semiconductor structure, creating a vertically integrated stack of dies formed within the substrates. The substrate bonding process carried out by the bonder module 190 ensures optimal electrical connections and minimal defects, resulting in high-performance, compact, and multi-functional semiconductor devices.

In the die-to-substrate bonding embodiment, individual dies are bonded to a receiving substrate (or wafer), which may contain pre-patterned bond pads or other structures for facilitating the bonding process. The dies and receiving substrate are first subjected to the cleaning, degassing, and plasma treatment as described previously. The bonders 190A, 190B are configured to pick up the individual dies, align them with the receiving substrate, and bond them using an integrated substrate bonding process. This process may involve aligning the bond pads on the dies with corresponding bond pads on the receiving substrate, and applying pressure and/or heat to form a strong bond between the dies and the receiving substrate. One or more embodiments described herein involve bonding multiple dies from a donor substrate to a host substrate simultaneously. In this approach, an entire array of dies is aligned and bonded to the host substrate in a single step. In other embodiments, individual dies from a donor substrate are bonded to a host substrate one at a time. In this approach, each die is picked, aligned, and bonded to the host substrate independently.

In the substrate-to-substrate bonding embodiment, two substrates with matching die or chiplet patterns are bonded together, forming the stacked semiconductor structure that includes stacked substrates. The substrates are first subjected to the cleaning, degassing, and plasma treatment as described previously. The bonders 190A, 190B are configured to align the substrates, ensuring accurate alignment of the bond pads or other structures on each substrate. Similar to the die-to-substrate bonding process, the aligned substrates are then bonded together using an integrated substrate bonding process, which may involve applying pressure and/or heat to form a strong bond between the two substrates.

### Processing Chamber Examples

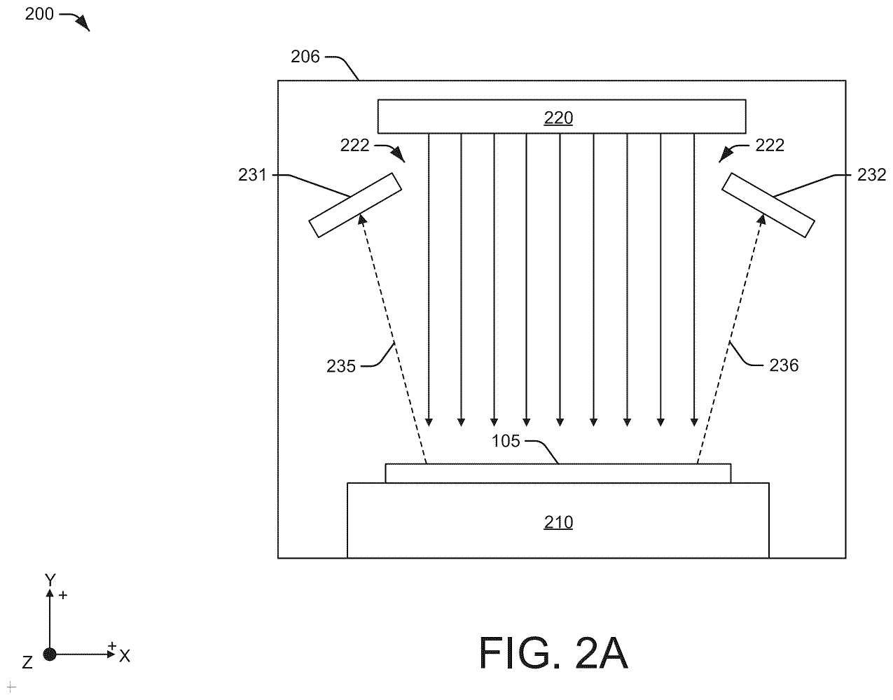

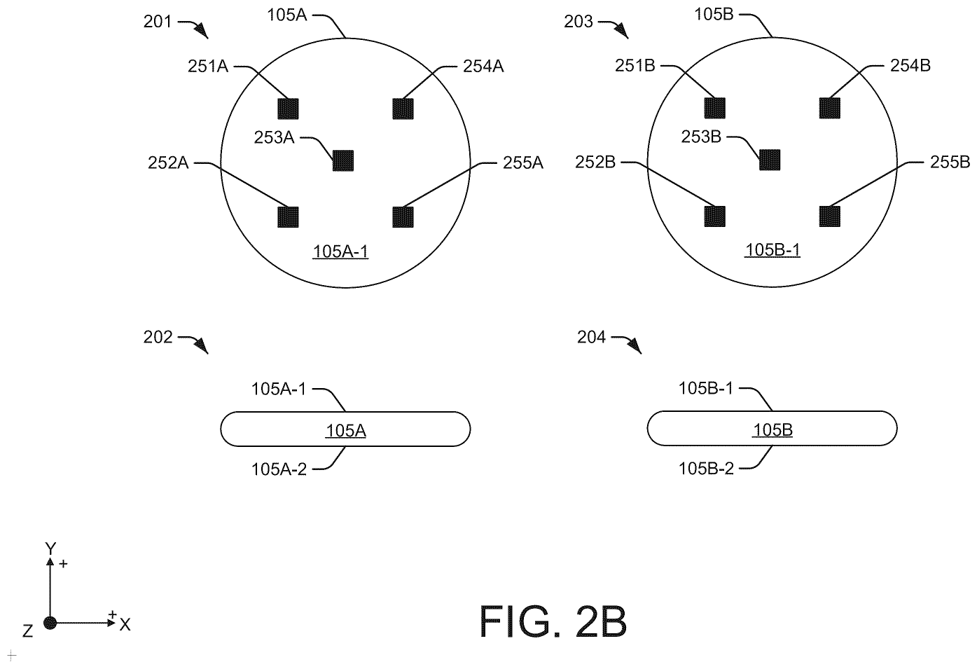

FIGS. 2A and 2B illustrate an example of substrates that can be used during a bonding process within a processing chamber 206. FIG. 2A illustrates a cross-sectional side view of an optical inspection system 200. In some embodiments, the optical inspection system 200 is included within the automated modular mainframes (AMMs) 130A, 130B. In other embodiments, the optical inspection system 200 is included as part of the AMM 130C. For example, the optical inspection system 200 can be included in a substrate aligner 132C and/or an in-line metrology system 134C of the AAM 130C.

The optical inspection system 200 is disposed in the processing chamber 206. Physical/environmental properties within the processing chamber 206 are controlled in order to facilitate substrate/wafer alignment via the optical inspection system 200. For example, the processing chamber 206 is sealed and isolated from other uncontrolled environments in order to prevent particulate or other contaminants from entering the processing chamber 206.

In some embodiments, the optical inspection system 200 includes a substrate 105 (which is representative of one or more of the source and target substrates 110A, 110B) disposed on a stage 210. A light source 220 positioned above the stage 210 directs electromagnetic radiation 222 towards the substrate 105 and the stage 210. In one or more embodiments, the light source 220 includes an infrared light source and the electromagnetic radiation 222 includes light having wavelengths in the infrared spectrum.

In various examples, the light source 220 directs electromagnetic radiation 222 of different wavelengths towards the substrate 105 and the stage 210. As shown, at least some of the electromagnetic radiation 222 reflects from the substrate 105, for example, as reflected electromagnetic radiation 235 towards a first image sensor 231 and as reflected radiation 236 towards a second image sensor 232. The first and second image sensors 231, 232 capture digital images based on the reflected radiation 235 and the reflected radiation 236, respectively. The system controller 112 processes the digital images and generates a map of the substrate 105. Using the map, the system controller 112 determines characteristics of the substrate 105 for alignment with another substrate such as the locations of features of the substrate 105 and critical dimensions of the features.

FIG. 2B illustrates a plan view 201 and a cross-sectional side view 202 of a first substrate 105A and a plan view 203 and a cross-sectional side view 204 of a second substrate 105B. In some embodiments, the first substrate 105A is included in the source substrates 110A and the second substrate 105B is included in the target substrates 110B. The first substrate 105A includes a topside 105A-1 and a bottom side 105A-2. The topside 105A-1 is configured to be bonded to a topside 105B-1 of the second substrate 105B as described below. The second substrate 105B also includes a bottom side 105B-2. In some embodiments, the topsides 105A-1, 105B-1 have been flattened, smoothed, cleaned, and/or activated as described above in order to bond the topsides 105A-1, 105B-1 together such that the first and second substrates 105A, 105B form a single composite structure.

The topside 105A-1 of the first substrate 105A includes multiple reference locations 251A-255A, which can include a die and/or chiplet formed on the surface of the substrate 105A. Similarly, the topside 105B-1 of the second substrate 105B also includes multiple reference locations 251B-255B, which can include a die and/or chiplet formed on the surface of the substrate 105B. In some embodiments, the system controller 112 utilizes maps of the first and second substrates 105A, 105B (e.g., generated form the digital images captured by the first and second image sensors 231, 232) in order to correlate ones of the reference locations 251A-255A with ones of the reference locations 251B-255B (e.g., globally and at the die level). These correlations can include computing differences in X-directions and Y-directions, computing angular misalignments (e.g., theta), computing linear misalignments (e.g., skew), computing scale factor differences (e.g., magnification errors), and various other measurements/computations. By correlating the reference locations 251A-255A with the reference locations 251B-255B, the system controller 112 can precisely align the first and second substrates 105A, 105B in order to bond the first and second substrates 105A, 105B.

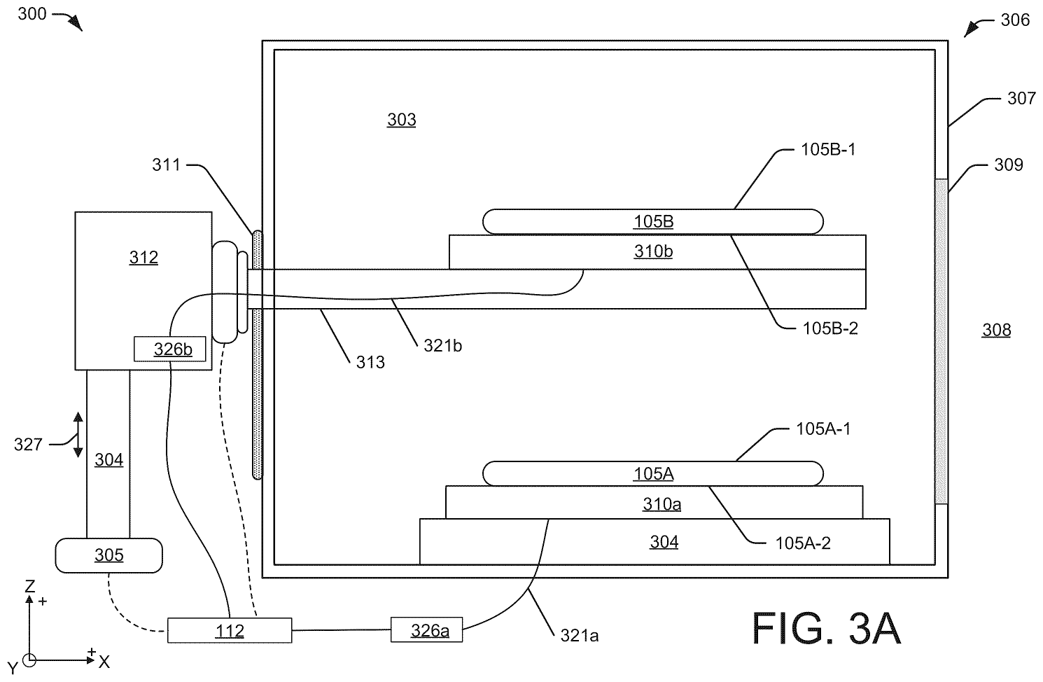

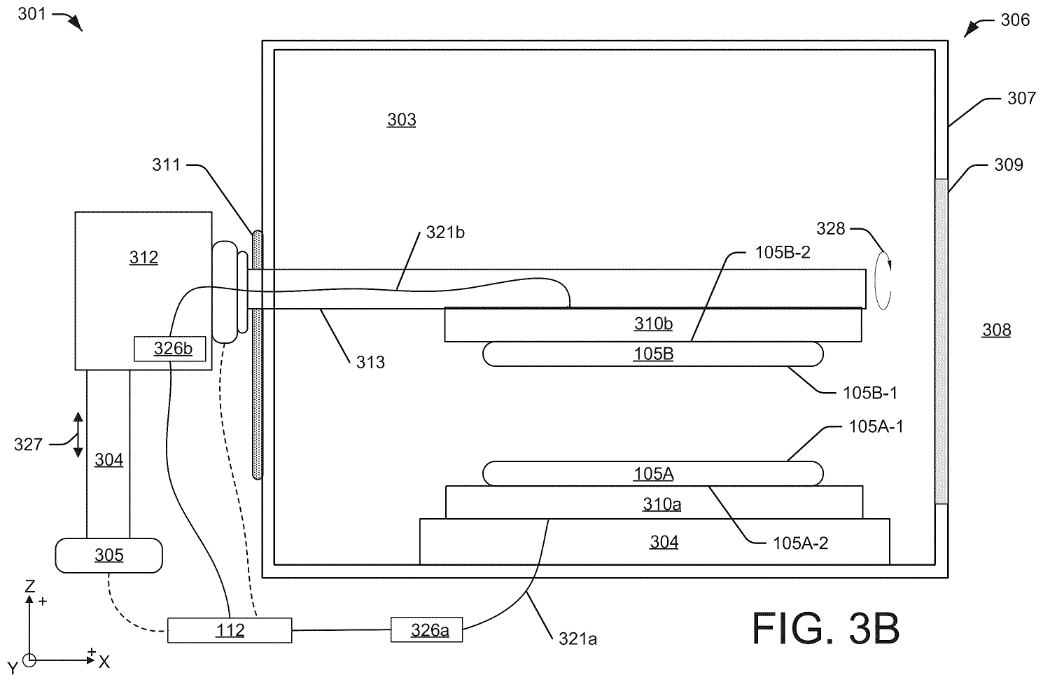

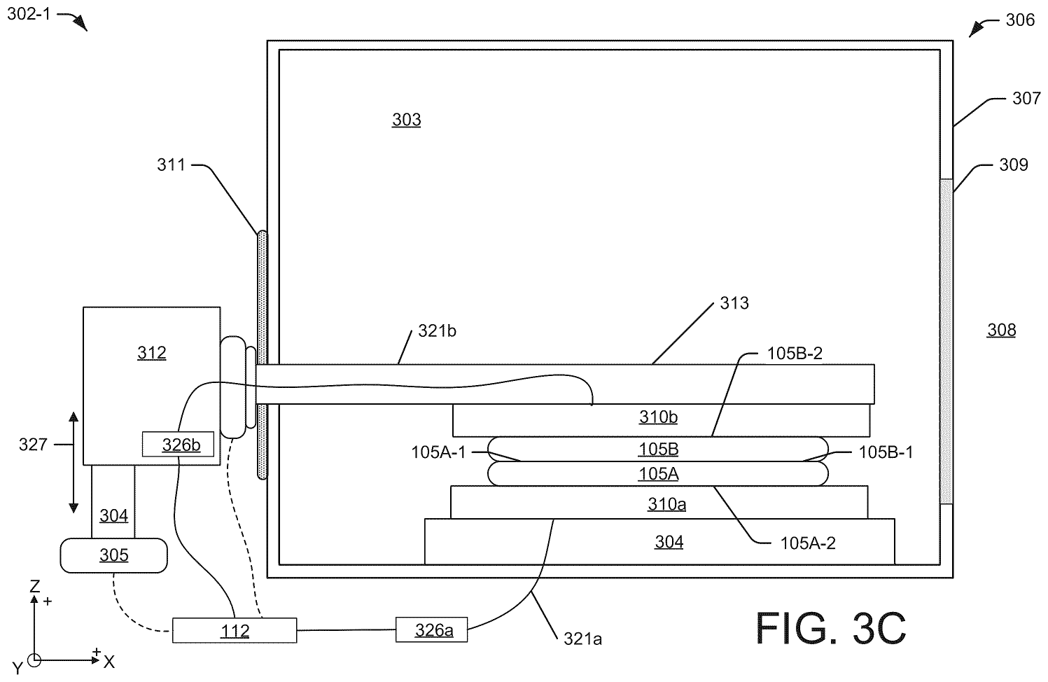

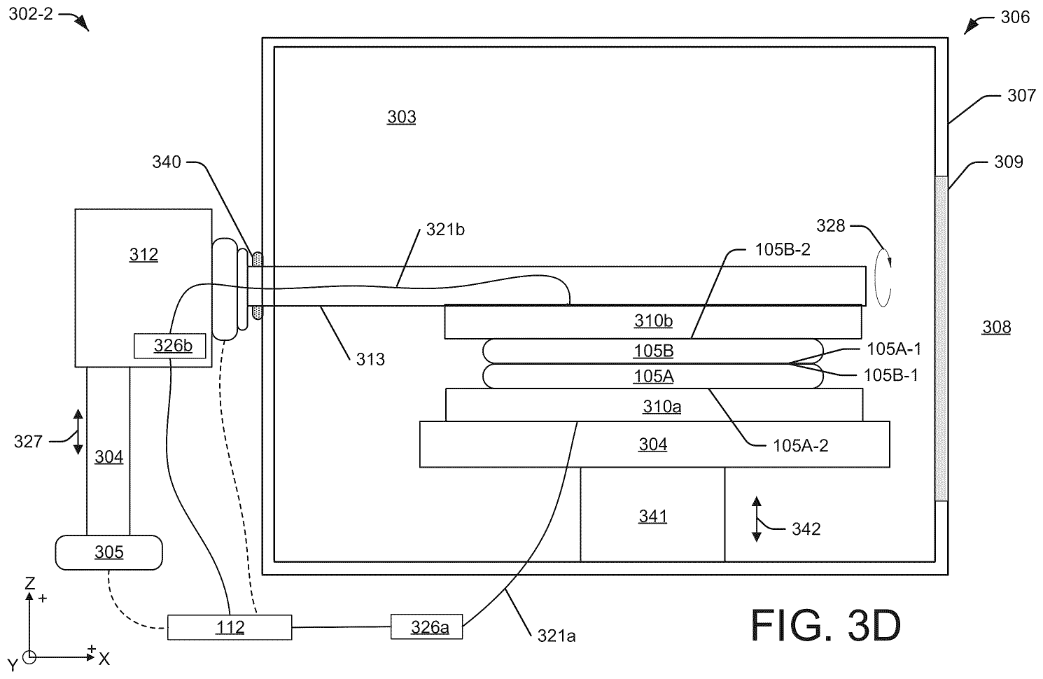

FIGS. 3A, 3B, 3C, and 3D are views of the source and target substrates at different times during a substrate bonding process. Like the processing chamber 206 described above, the processing chamber 306 is sealed and isolated from other uncontrolled environments in order to prevent particulate or other contaminants from entering the processing chamber 306. FIG. 3A illustrates a cross-sectional side view 300 of a substrate alignment/rotation system with a first substrate 105A chucked to a surface of a first electrostatic chuck (ESC) 310a and a second substrate 105B chucked to a surface of a second ESC 310b. A first voltage source 326a is electrically coupled to the first ESC 310a. Similarly, a second voltage source 326b is electrically coupled to the second ESC 310b. In some embodiments, the substrate alignment/rotation system illustrated in the side view 300 is included in the bonding module 190.

As shown, the substrate alignment/rotation system includes a processing region 303 enclosed within one or more walls 307 of the processing chamber 306. The first ESC 310a is disposed on a stage 304 within the processing region 303 and the second ESC 310b is disposed on a rotation arm 313 of a rotation system 312 within the processing region 303. In some embodiments, the rotation system 312 is at least partially isolated from the processing region 303 by a seal assembly 311 (e.g., bellows, boot, etc.). The seal assembly 311 is configured to allow rotational motion to be transferred from the rotation system 312 to the rotation arm 313 while maintaining a vacuum environment within the processing region 303. In some other embodiments of the processing chamber 306, the rotation system 312 is disposed within the processing region 303, and thus a seal assembly 311 is not required.

The seal assembly 311 is also configured to facilitate vertical actuation of the rotation system 312 in directions 327 which are in the Z-direction while maintaining a controlled atmospheric pressure environment and/or vacuum environment within the processing region 303. For example, an actuator 305 is capable of actuating the rotation system 312 in the positive Z-direction and in the negative Z-direction by extending and retracting a base 304 of the rotation system 312, respectively. In one or more embodiments, the system controller 112 controls the actuator 305 and the system controller 112 causes the actuator 305 to extend or retract the base 304 of the rotation system 312 in the directions 327.

In some embodiments, a factory robot (not shown) accesses the processing region 303 via a slit valve 309 which is configured to provide a seal between the processing region 303 and an external region 308 (e.g., to prevent gases from transferring between the processing region 303 and the external region 308). In one or more embodiments, the slit valve 309 is configured to maintain the vacuum environment within the processing region 303 as the factory robot enters the processing region 303 from the external region 308 and as the factory robot enters the external region 308 from the processing region 303. The factory robot disposes the first substrate 105A on the first ESC 310a over the stage 304 and the factory robot disposes the second substrate 105B on the second ESC 310b over the rotation arm 313.

As shown in FIG. 3A, the bottom side 105A-2 of the first substrate 105A interfaces with a surface of the first ESC 310a while the topside 105A-1 of the first substrate 105A is oriented in a first direction within the processing region 303. The first direction is facing in the positive Z-direction towards the rotation arm 313 of the rotation system 312 with respect to a location of the first substrate 105A within the processing region 303. The bottom side 105B-2 of the second substrate 105B interfaces with a surface of the second ESC 310b and the topside 105B-1 of the second substrate 105B is oriented in the first direction within the processing region 303.

As described with respect to FIG. 2B, the topside 105B-1 of the second substrate 105B is configured to be bonded to the topside 105A-1 of the first substrate 105A. For example, the topsides 105A-1, 105B-1 have been cleaned, activated, and aligned for bonding. However, the topsides 105A-1, 105B-1 are not capable of interfacing with one another in order to bond the first and second substrates 105A, 105B while the topsides 105A-1, 105B-1 are both oriented in the first direction within the processing region 303.

FIG. 3B illustrates a cross-sectional side view 301 of the substrate alignment/rotation system with the second substrate 105B and the second ESC 310b rotated 180 degrees about an X-direction axis within the processing region 303. A wiring assembly 321b, which is disposed within the rotation arm 313, is used to connect the components within the second ESC 310b to the second voltage source 326b and allow the second ESC 310b to rotate freely within the processing region 303 without tangling the pneumatic and/or electrical lines within the wiring assembly 321b. In some embodiments, the CPU 114 of the system controller 112 executes instructions that cause the CPU 114 to control the rotation system 312 and rotate the rotation arm 313 in a rotational direction 328 by about 180 degrees within the processing region 303. After the rotation of the rotation arm 313 in the rotational direction 328 within the processing region 303, the topside 105B-1 of the second substrate 105B is oriented in a second direction that is opposite to the first direction. In other words, the topside 105B-1 of the second substrate 105B and the topside 105A-1 of the first substrate 105A are facing each other, and in some cases parallel to each other. Accordingly, after the topsides 105A-1, 105B-1 are oriented to face each other the topsides 105A-1, 105B-1 of the first and second substrates 105A, 105B, respectively, can be bonded together to form the single composite structure.

FIG. 3C illustrates a cross-sectional side view 302-1 of the substrate alignment/rotation system with the topside 105B-1 of the second substrate 105B actuated towards the topside 105A-1 of the first substrate 105A within the processing region 303. In one or more embodiments, the CPU 114 of the system controller 112 executes instructions that cause the CPU 114 to control the actuator 305 and retract the base 304. Retracting the base 304 causes the rotational system 312 to actuate in negative Z-direction which actuates the second substrate 105B towards the first substrate 105A within the processing region 303. In some embodiments, the actuator 305 retracts the base 304 until the topside 105B-1 of the second substrate 105B contacts the topside 105A-1 of the first substrate 105A. However, in other embodiments, the actuator 305 retracts the base 304 until the topside 105B-1 of the second substrate 105B is separated from the topside 105A-1 of the first substrate 105A by a relatively small distance. For example, when the topsides 105A-1, 105B-1 are separated by the relatively small distance within the processing region 303, components within the first and second ESCs 310a, 310b can be leveraged to bond the first and second substrates 105A, 105B and avoid the disadvantages associated with conventional bonding techniques such as use of adhesives or thermal compression. Examples of components within the one or more of the substrate retaining elements, (e.g., ESCs) that can be used to facilitate the bonding process are further described below.

FIG. 3D illustrates a cross-sectional side view 302-2 of the substrate alignment/rotation system with the topside 105A-1 of the first substrate 105A actuated towards the topside 105B-1 of the second substrate 105B within the processing region 303. As an alternative to FIG. 3C, the seal assembly 311 may be replaced with a rotation seal 340. The CPU 114 of the system controller 112 executes instructions that cause the CPU 114 to control an actuator 341 which actuates in directions 342. In some embodiments, the actuator 341 actuates in the positive Z-direction to actuate the topside 105A-1 of the first substrate 105A towards the topside 105B-1 of the second substrate 105B until the topside 105A-1 of the first substrate 105A is separated from the topside 105B-1 of the second substrate 105B by the relatively small distance. Notably, in the example illustrated in FIG. 3D, the rotation seal 340 may be advantageous relative to the seal assembly 311, for example, in maintaining the vacuum environment within the processing region 303.

### Substrate Retaining Element Examples

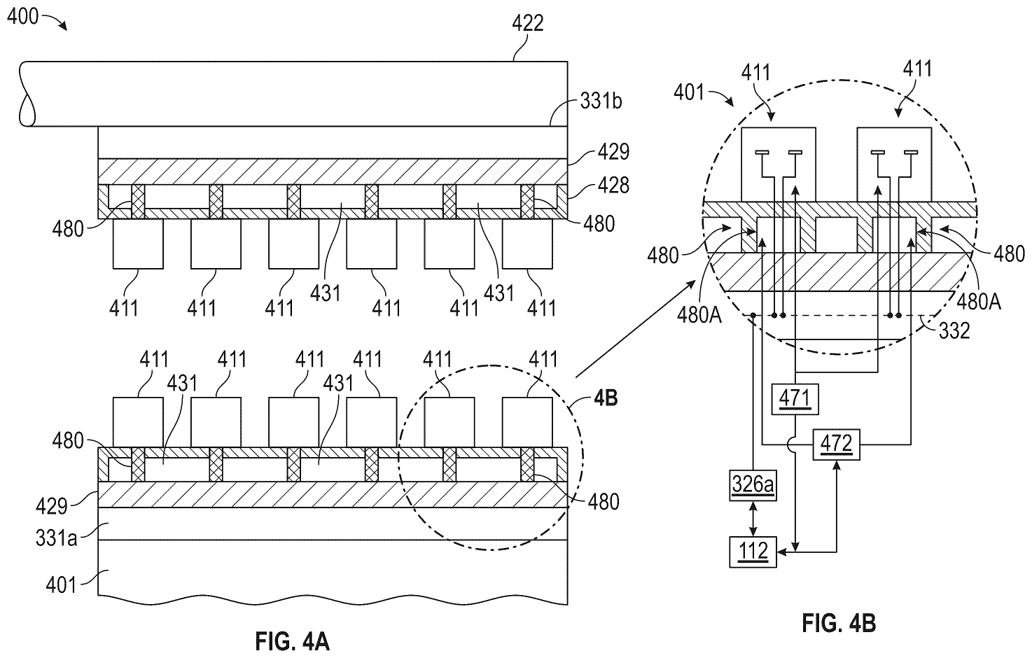

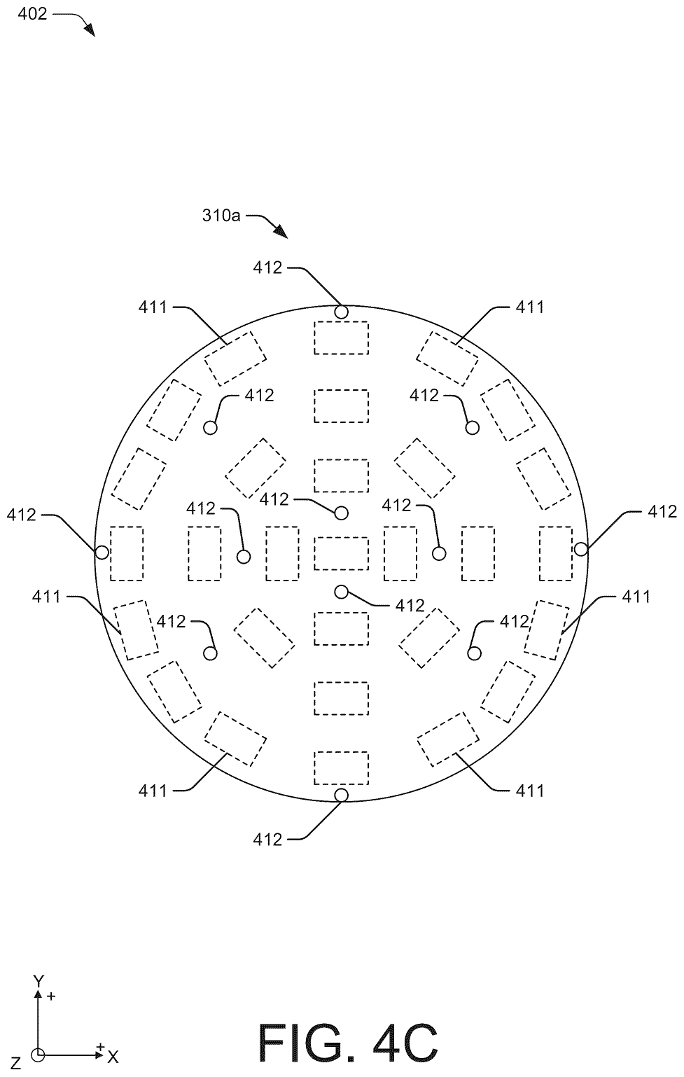

FIGS. 4A, 4B, and 4C are schematic representations of substrate retaining elements, which are referred to herein as electrostatic chucks (ESCs) 310a, 310b, which each include multiple segments 411 that can be used during a bonding process. FIG. 4A illustrates a cross-sectional side view 400 of a first and a second ESC 310a, 310b. As shown in the side view 400, each of the segments 411 is coupled to an actuator 480 and each of the actuators 480 is capable of actuating a corresponding segment 411 independently of the other segments 411. The actuators 480 are representative of a variety of different types of actuators capable of adjusting positions of the segments 411. In various embodiments, the actuators 480 may be electrical (e.g., including a solenoid actuator, a DC motor, a stepper motor, a linear motor, etc.), hydraulic, electrohydraulic, pneumatic, piezoelectric, magnetostrictive, and/or any other type of actuator. In some embodiments, the actuators 480 comprises a flexible membrane that at least partially encloses an inner volume 480A. In some cases, each of the actuators 480 are separately capable of expanding and contracting as a pressure within the inner volume 480A is adjusted by the delivery and removal of a fluid and/or evacuated by a vacuum generating device.

In some embodiments, the first and second ESCs 310a, 310b each include “pixelated” temperature controlling elements (not shown) which are capable of multidirectional (e.g., both lateral and azimuthal) adjustment of a temperature of the first and second ESCs 310a, 310b. The multidirectional adjustability enables the pixelated temperature controlling elements to control the temperature locally in particular portions (not shown) of the first and second ESCs 310a, 310b. The system controller 112 can control the pixelated temperature controlling elements (e.g., resistive heating elements) which allow system controller 112 to change temperatures locally within the particular portions to improve accuracy of wafer/substrate overlay and bonding process. The pixelated temperature controls along with the segments 411 of the first and second ESCs 310a, 310b can provide improved wafer/substrate flattening capabilities for both the first and second ESCs 310a, 310b relative to ESCs without multiple segments 411 or the pixelated temperature controlling elements.

A membrane 428 and a supporting structure 429 of the first and second ESCs 310a, 310b form one or more inner membrane regions 431 below the segments 441 which can be pressurized by delivering one or more fluids or evacuated via backside gas delivery ports (not shown). The segments 411 are coupled to the membrane 428 (e.g., at bottom sides of the segments 411) such that an actuation of a segment 411 is configured to actuate a portion of the membrane 428 that is coupled to the segment 411. In various embodiments, a portion of the segments 411 is fixed to a portion of the membrane 428, for example, by an adhesive, an epoxy, a metal-joining process (e.g., welding, brazing, etc.), or the like to allow a seal and/or a bond to be formed between these components.

In some embodiments, the membrane 428 includes a flexible thin walled metal plate or a fluoroelastomer material such as a perfluoroelastomer material. In one or more embodiments, the membrane 428 is generally flexible such that a portion of the membrane 428 may deform if a force is applied to the portion. In certain embodiments, the membrane 428 is at least partially extendable relative to the supporting structure 429, for example, by actuating one or more actuators 480 to extend one or more segments 411 relative to substrate supports 331a, 331b of the first and second ESCs 310a, 310b, respectively. In some embodiments, the membrane 428 is extendable relative to the supporting structure 429 by a distance in a range of about 0.1 to 8.0 millimeters. In other embodiments the membrane 428 is extendable relative to the supporting structure 429 by a distance of less than about 0.1 millimeters or greater than about 8.0 millimeters.

In one example, the membrane 428 comprises a thin metal or polymer disk that encloses the pressurizable inner membrane region(s) 431 formed within the substrate supports 331a, 331b of the first and second ESCs 310a, 310b, respectively. The pressurizable inner membrane region 431 is configured to cause movement (e.g., deformation) of a surface of the membrane 428 due to an adjustment of a fluid pressure or application of a vacuum pressure applied to the pressurizable inner membrane region 431. In one or more examples, the membrane 428 is formed from a metal material, such as Hastelloy, Haynes 202, various nickel alloys, stainless steel, or the like.

FIG. 4B illustrates an enlarged cross-sectional side view 401 of a portion of the first ESC 310a. Although the side view 401 illustrates a portion of the first ESC 310a, it is to be appreciated that the functionality described to be included in the first ESC 310a may also be included in the second ESC 310b. The substrate support 331a includes a circuit layer 332 of a printed circuit board (PCB) which electrically couples the first voltage source 326a to pairs of electrodes that are disposed within the segments 411. In some embodiments, the circuit layer 332 includes multiple transistors (e.g., MOSFETs) configured as switches for coupling/decoupling the first voltage source 326a and the pairs of electrodes disposed within the segments 411. For example, the first voltage source 326a is capable of outputting example voltages of ±5000 V, ±10,000 V, ±20,000 V, etc. that can be applied to the pairs of electrodes to generate a DC bias between the pairs of electrodes which generates corresponding electrostatic forces. While not intending to be bound by theory, generated electrostatic forces are typically capable of attracting a portion of the first and second substrates 105A, 105B to surfaces of the first and second ESCs 310a, 310b (e.g., surfaces of the segments 411) if the portion is a relatively small distance (e.g., one millimeter) from the pair of electrodes. In one non-limiting example, when a bias voltage of about 1 kV for a Johnsen-Rahbek ESC and about 3 kV for a Coulombic ESC is applied between a pair of electrodes, the applied bias is able to cause movement in a portion of a silicon substrate that is spaced about one millimeter from the surfaces of the first and second ESCs 310a, 310b (e.g., surfaces of the segments 411).

In some embodiments, a gas delivery system 472 may be available to the first and second ESCs 310a, 310b. In one or more embodiments, a vacuum source 471 may also be available to the first and second ESCs 310a, 310b. In various embodiments, segments 411 may include one or more vacuum chucking ports (not shown) and/or one or more backside gas delivery ports (not shown). The gas delivery system 472 can deliver a gas (e.g., an inert gas) through the backside gas delivery ports and the vacuum source 471 may provide a vacuum pressure via vacuum chucking ports (shown in FIG. 4C). As shown in FIG. 4B, the system controller 112 controls delivery of gas through the backside gas delivery ports and/or provision of vacuum pressure via the vacuum chucking ports.

In one or more embodiments, the first and second ESCs 310a, 310b include capacitive sensors (not shown) that are configured to measure distances (e.g., in substantially real-time) between surfaces of segments 411 and the bottom sides 105A-2, 105B-2 of the first and second substrates 105A, 105B, respectively. In some embodiments, the system controller 112 is capable of measuring distances between surfaces of segments 411 and the bottom sides 105A-2, 105B-2 using mechanical displacements of one or more actuators 480, using the optical inspection system 200, and/or using another measurement system. For example, the system controller 112 can measure (e.g., in substantially real-time) curvatures of the first and second substrates 105A, 105B.

Additionally, in some embodiments, the first and second ESCs 310a, 310b include the pixelated temperature zones (not shown). Local temperatures within pixelated temperature zones can be measured using one or more thermal sensors (not shown). For example, the local temperatures may be measured after temperature stabilization, and the local temperatures within the pixelated temperature zones can be adjusted by the pixelated temperature controls as needed to match desired local temperatures.

FIG. 4C illustrates a plan view 402 of an example arrangement of segments 411 of the first ESC 310a. Although the plan view 402 illustrates an arrangement of segments 411 and vacuum chucking ports 412 of the first ESC 310a, it is to be appreciated that the arrangement of segments 411 and vacuum chucking ports 412 described to be included in the first ESC 310a can also be included in the second ESC 310b. As shown in the plan view 402, the first ESC 310a may include 29 segments 411. In some embodiments, a central segment 411 is disposed within four segments 411 which are disposed within eight segments 411 that are disposed within 16 segments 411.

Vacuum chucking ports 412 are coupled to the vacuum source 471 via vacuum conduits (not shown). Vacuum pressure from the vacuum source 471 is available at the vacuum chucking ports 412 via the vacuum conduits to apply vacuum chucking forces to the first substrate 105A which may be used to immobilize the first substrate 105A on surfaces of the segments 411 or used to selectively deform the first substrate 105A as described below. In one or more embodiments, the segments 411 are spaced about 5 millimeters apart and the actuators 480 can include ball joints (not shown) which facilitate a range of motion for the segments 411 in the X-direction and the Y-direction. Although the example shown in FIG. 4C includes 29 segments 411, it is to be appreciated that in some embodiments, the first ESC 310a includes more than 29 segments 411 or less than 29 segments. Notably, a surface of the first ESC 310a may be flat in some embodiments and the surface of the first ESC 310a may be curved in other embodiments such that edges of the first ESC 310a and/or edges of the segments 411 do not rub or interact during various actuations. For example, the surface of the first ESC 310a may be configured to prevent interactions with edges such as a particular geometry configured to prevent the interactions with edges.

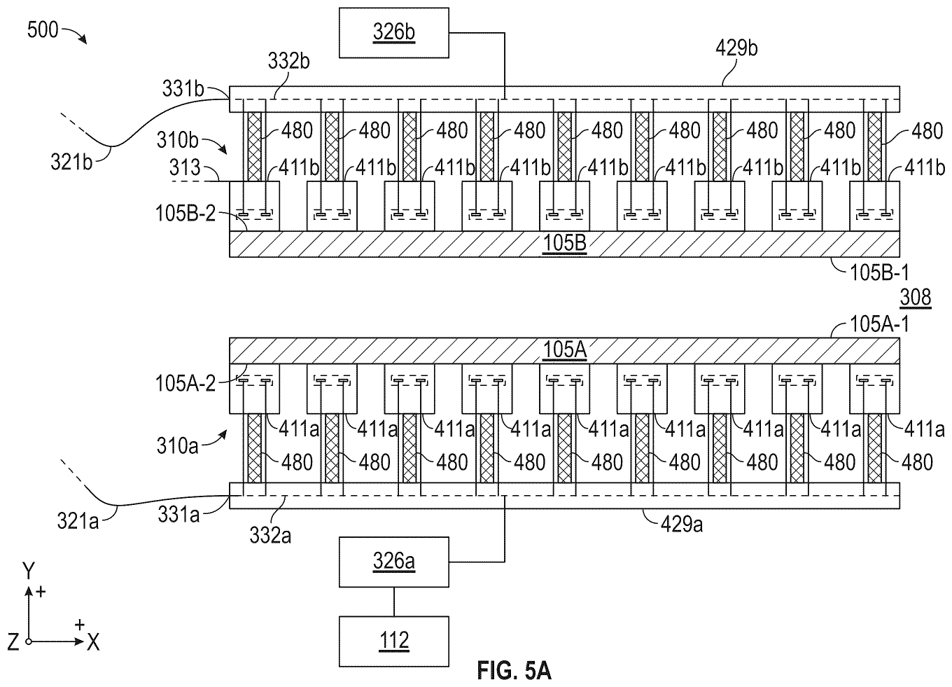

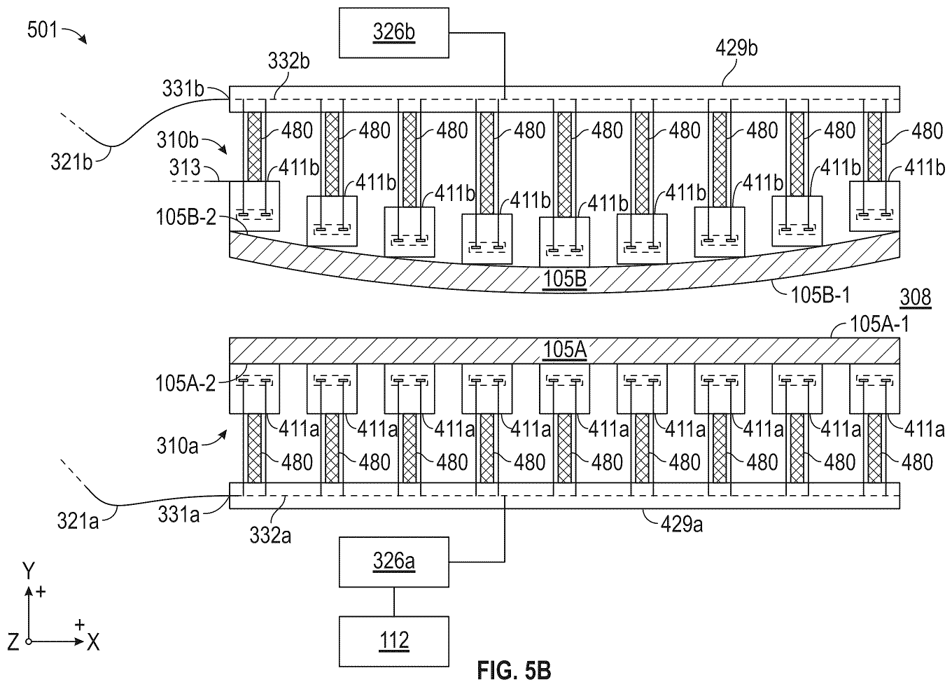

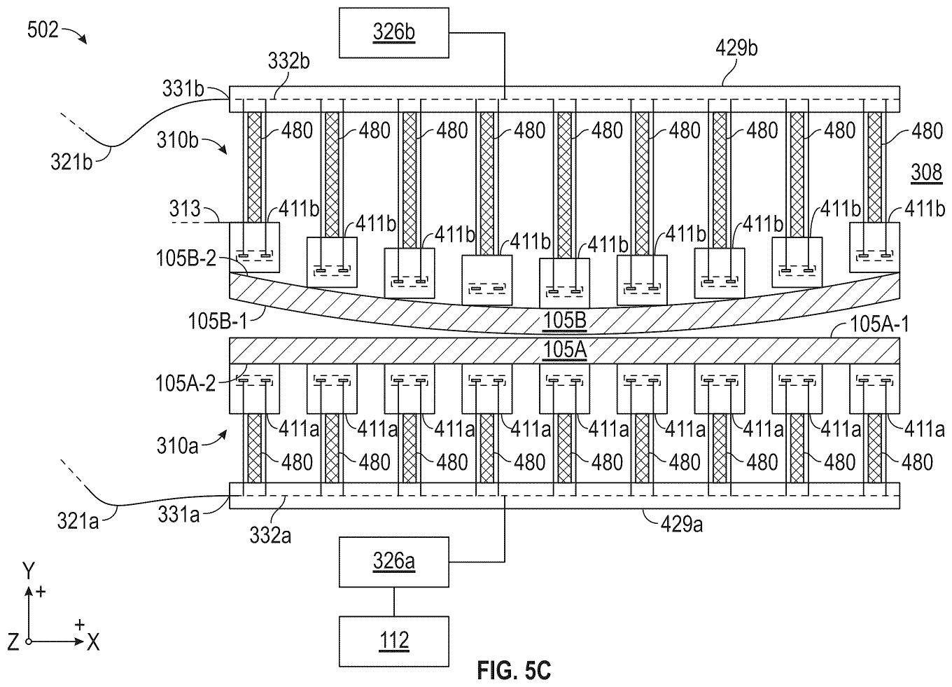

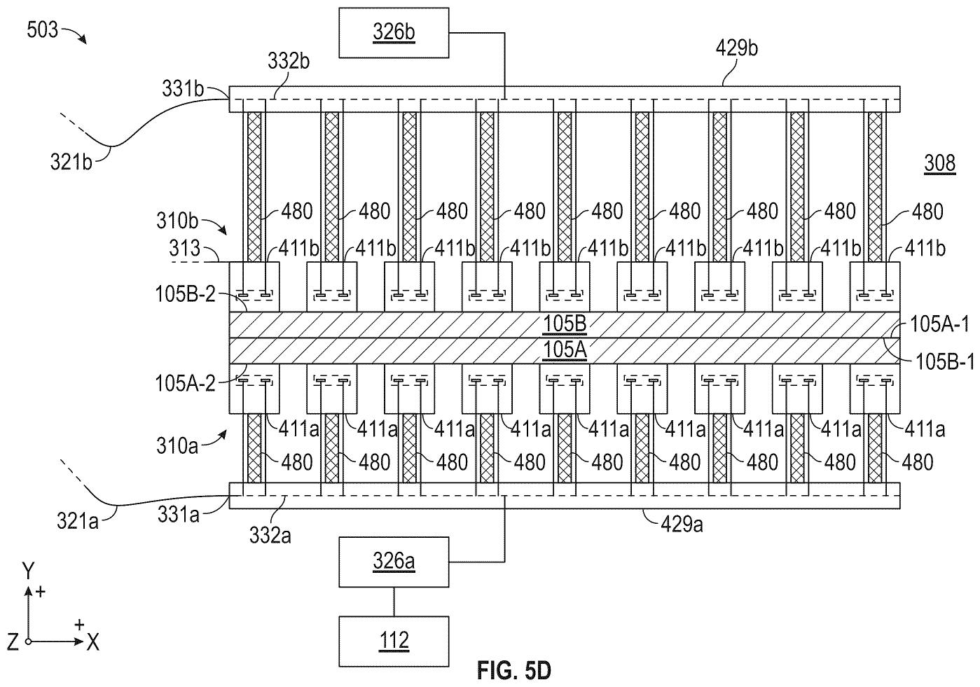

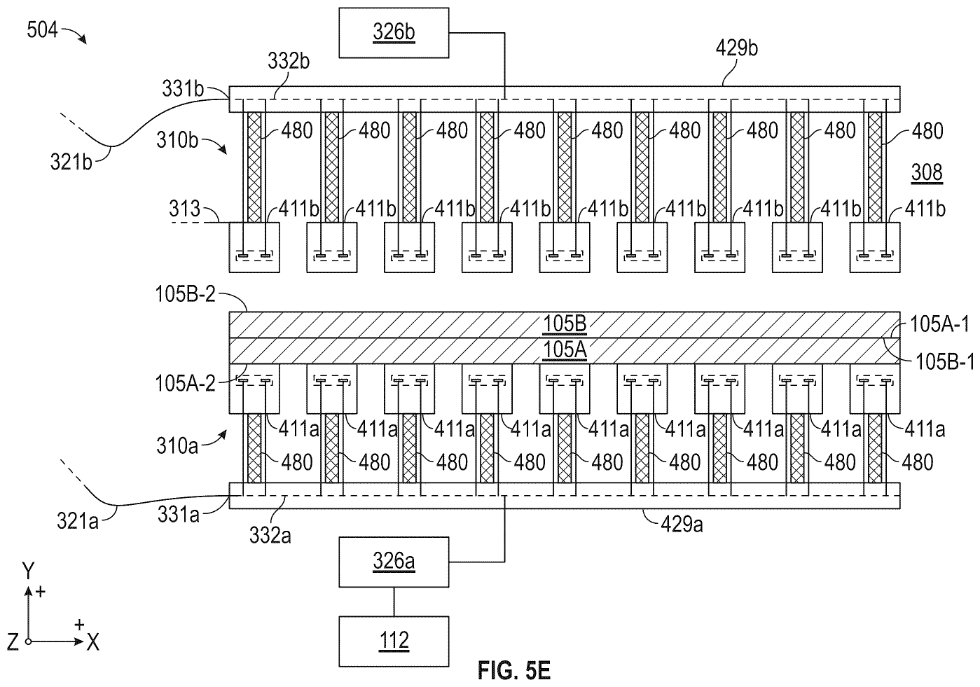

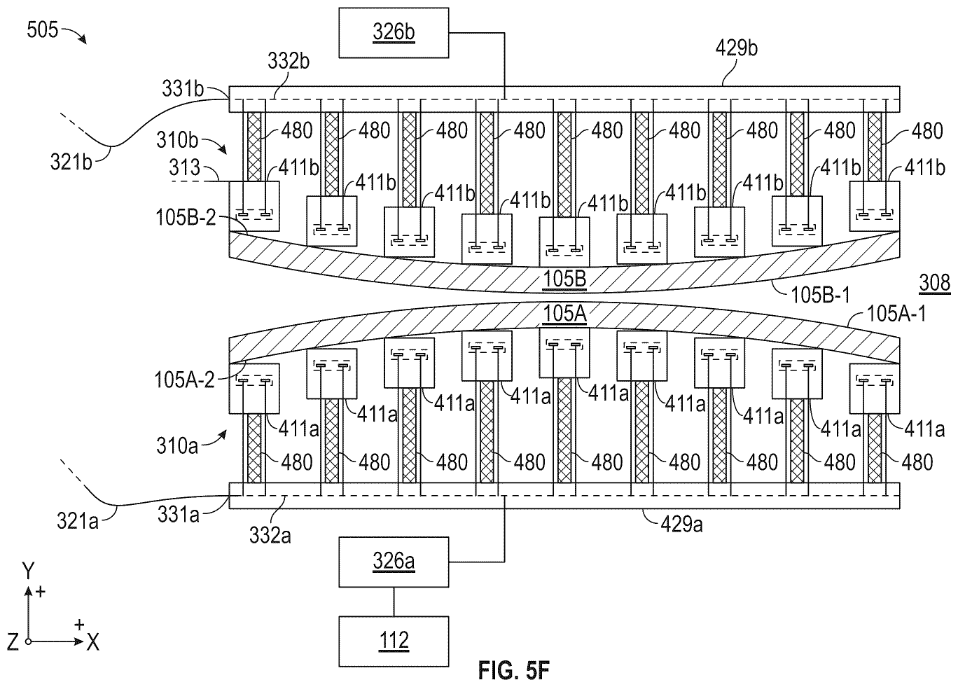

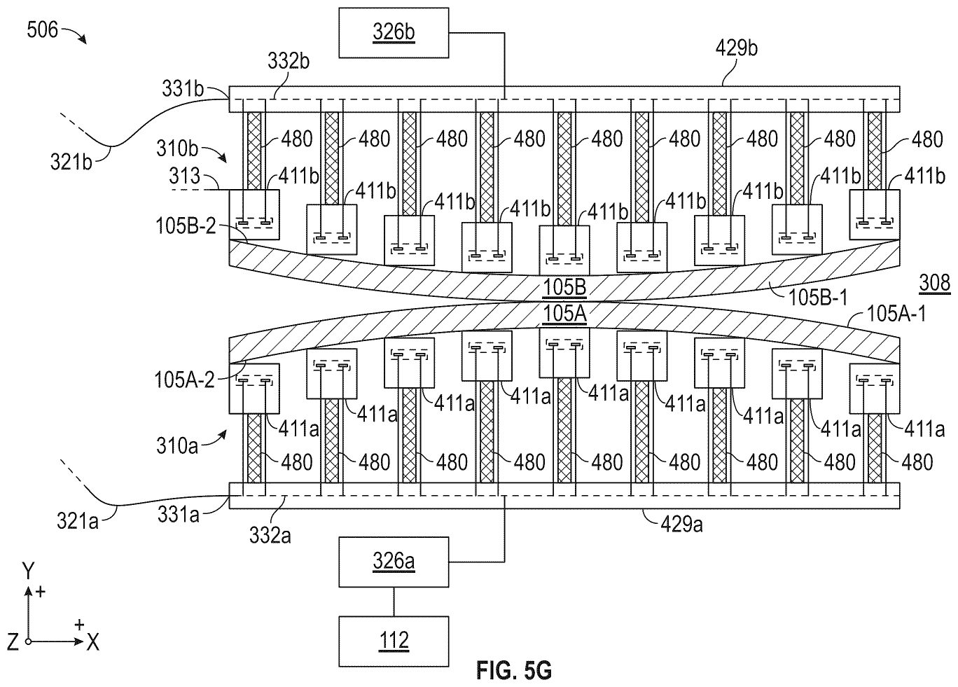

FIGS. 5A, 5B, 5C, 5D, 5E, 5F, and 5G illustrate cross-sectional views of examples of electrostatic chucks (ESCs) that can each be used to distort the shape of a substrate during a bonding process. FIG. 5A illustrates a cross-sectional side view 500 of the topside 105B-1 of the second substrate 105B separated from the topside 105A-1 of the first substrate 105A by a relatively small distance.

FIG. 5B illustrates a cross-sectional side view 501 of the second substrate 105B bowed to have a convex curvature relative to the first substrate 105A. For example, a medial portion (or center point) of the bottom side 105B-2 of the second substrate 105B extends a distance from a bottom side edge of the substrate in a range of about 0.2 to 1.0 millimeters.

FIG. 5C illustrates a cross-sectional side view 502 of the second substrate 105B after it has been positioned to initially contact the topside 105A-1 of the first substrate 105A. The medial portion of the topside 105B-1 of the second substrate 105B contacts the topside 105A-1 of the first substrate 105A before a lateral portion of the topside 105B-1 of the second substrate 105B contacts the topside 105A-1 of the first substrate 105A.

FIG. 5D illustrates a cross-sectional side view 503 in which the topside 105B-1 of the second substrate 105B bonded to the topside 105A-1 of the first substrate 105A. In one or more embodiments, after the medial portion of the topside 105B-1 of the second substrate 105B contacts the topside 105A-1 of the first substrate 105A, the lateral portion of the topside 105B-1 of the second substrate 105B contacts the topside 105A-1 of the first substrate 105A which bonds the first and second substrates 105A, 105B.

FIG. 5E illustrates a cross-sectional side view 504 of retracting the second ESC 310b from the bonded first and second substrates 105A, 105B. In some embodiments, after the second substrate 105B is bonded to the first substrate 105A, the system controller 112 causes the second voltage source 326b to halt application of the DC biases to pairs of electrodes disposed in the segments 411 of the second ESC 310b. Halting the DC biases applied to the pairs of electrodes also halts the electrostatic forces chucking the second substrate 105B to the second ESC 310b. After halting the electrostatic forces, the second ESC 310b is retracted from the second substrate 105B as shown in the side view 504.

FIG. 5F illustrates a cross-sectional side view 505 of a pre-bonding configuration, similar to FIG. 5B, in which the second substrate 105B is bowed to have a convex curvature relative to the first substrate 105A and the first substrate 105A bowed to have a convex curvature relative to the second substrate 105B. Medial portions of the bottom side 105A-2 of the first substrate 105A and the bottom side 105B-2 of the second substrate 105B extend from surfaces of segments of the first ESC 310a and the second ESC 310b, respectively. The medial portion of the bottom side 105A-2 of the first substrate 105A may extend a first distance from a surface one or more segments 411 of the first ESC 310a in a range of about 0.2 to 1.0 millimeters. Similarly, the medial portion of the bottom side 105B-2 of the second substrate 105B can extend a second distance from a surface of one or more segments 411 of the second ESC 310b in a range of about 0.2 to 1.0 millimeters.

FIG. 5G illustrates a cross-sectional side view 506 of the first and second substrates 105A, 105B initially contacting one another, which is similar to FIG. 5C, and before the substrates are bonded together as previously shown and described in relation to FIGS. 5D-5E. The medial portion of the topside 105A-1 of the first substrate 105A contacts the medial portion of the topside 105B-1 of the second substrate 105B before a lateral portion of the topside 105A-1 of the first substrate 105A contacts a lateral portion of the topside 105B-1 of the second substrate 105B.

### Substrate-to-Substrate Bonding Examples

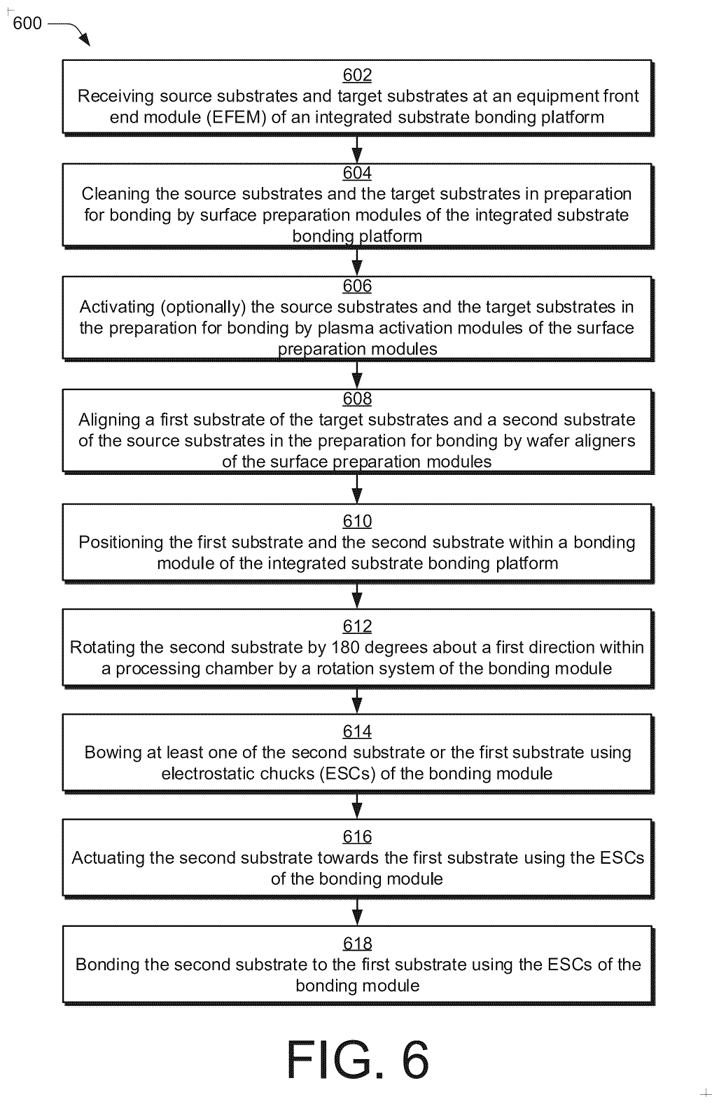

FIG. 6 is a process flow diagram illustrating a method 600 for bonding substrates using electrostatic chucks (ESCs) during one or more portions of a bonding process sequence. At operation 602, source substrates and target substrates are received at an equipment front end module (EFEM) of an integrated substrate bonding platform. With reference to FIG. 1, the EFEM 102 of the integrated substrate bonding platform 100 receives the source substrates 110A included in one or more front opening unified pods (FOUPs) and the target substrates 110B included in one or more FOUPs. The EFEM 102 includes one or more factory interface robots 113 that unload the source substrates 110A from the one or more FOUPs and also unload the target substrates 110B from the one or more FOUPs. After unloading the source substrates 110A and the target substrates 110B, the one or more factory interface robots 113 transfer the source substrates 110A and the target substrates 110B into the surface preparation modules 104, 106.

At operation 604, the source substrates and the target substrates are cleaned in preparation for bonding by surface preparation modules of the integrated bonding platform. Referring to FIG. 1, after the one or more factory interface robots 113 transfer the source substrates 110A and the target substrates 110B into the surface preparation modules 104, 106, a series of cleaning operations are performed on the source and target substrates 110A, 110B. Examples of the cleaning operations that may be performed on the source and target substrates 110A, 110B include an initial cleaning (e.g., a solvent cleaning/bath), a wet cleaning (e.g., a chemical cleaning using a mixture of sulfuric acid (H₂SO₄) and hydrogen peroxide (H₂O₂)), a rinsing (e.g., a deionized water rinsing), a drying (e.g., a nitrogen blow drying), and other cleaning operations. In some embodiments, the surface preparation modules 104, 106 include the automated modular mainframes (AMMs) 130A, 130B, the degas modules 160A, 160B, and the plasma activation modules 170A, 170B. The degas modules 160A, 160B are configured for outgassing the source and target substrates 110A, 110B by removing residual liquids, gases and contaminants that may have been adsorbed or trapped on the substrate surfaces during prior processing steps which ensures that surfaces of the source and target substrates 110A, 110B are free of contaminants that might interfere with subsequent processing steps.

At operation 606, the source substrates and the target substrates are optionally activated in the preparation for bonding by plasma activation modules of the surface preparation modules. As shown in FIG. 1, after the source substrates 110A and the target substrates 110B have been cleaned by the cleaning operations, the source and target substrates 110A, 110B are loaded into one or more plasma processing chambers of the plasma activation modules 170A, 170B. The plasma processing chambers are sealed and pumped down to generate low pressure environments within the plasma processing chambers such as vacuum environments.

As described above, the plasma activation modules 170A, 170B are configured to utilize a range of remote plasma source (RPS) or direct RF plasma clean or activation processes that include the use of gas chemistries, comprising, but not limited to at least one of H₂, N₂, Ar, He, NH₃, and NF₃. Plasmas are formed in the plasma processing chambers, and the source and target substrates 110A, 110B are exposed to the plasmas in the plasma processing chambers for a predetermined amount of time. After exposing the source and target substrates 110A, 110B for the predetermined amount of time, the plasma processing chambers are vented and the activated source and target substrates 110A, 110B are unloaded from the plasma processing chambers.

At operation 608, a first substrate of the target substrates and a second substrate of the source substrates are aligned in the preparation for bonding by substrate aligners of the surface preparation modules. As described above with reference to FIG. 1, the AMMs 130A, 130B comprises the substrate aligners 132A, 132B and the in-line metrology systems 134A, 134B, respectively. These components work in tandem to ensure proper substrate alignment and verification of surface characteristics before and after the surface preparation process.

With reference to FIGS. 2A and 2B, the optical inspection system 200 uses the first and second image sensors 231, 232 to generate digital images of the first substrate 105A and the second substrate 105B based on the reflected radiation 235 and the reflected radiation 236, respectively, from the first and second substrates 105A, 105B. The system controller 112 can then generate a map of the surface of the first and second substrates 105A, 105B based on the digital images. In some embodiments, the system controller 112 utilizes the map of the surfaces of the first and second substrates 105A, 105B in order to correlate ones of the reference locations 251A-255A with ones of the reference locations 251B-255B. As described above, these correlations can include computing the differences in X-directions and Y-directions, computing the angular misalignments (e.g., theta), computing the linear misalignments (e.g., skew), computing the scale factor differences (e.g., magnification errors), and the various other measurements/computations. By correlating the reference locations 251A-255A with the reference locations 251B-255B, the system controller 112 can precisely align the first and second substrates 105A, 105B.

At operation 610, the first and second substrates 105A, 105B are positioned within a bonding module of the integrated substrate bonding platform. As described above relative to FIG. 1, the bonding module 190 includes the bonders 190A, 190B. In some embodiments, the bonders 190A, 190B include the substrate alignment/rotation system illustrated in FIG. 3A. As shown in FIG. 3A, the substrate alignment/rotation system includes the processing region 303 enclosed within the wall 307 of the processing chamber 306. The first ESC 310a is disposed on the stage 304 within the processing region 303 and the second ESC 310b is disposed on the rotation arm 313 of a rotation system 312 within the processing region 303.

The factory robot (not shown) accesses the processing region 303 via the slit valve 309. The factory robot disposes the first substrate 105A on the first ESC 310a over the stage 304 and the factory robot disposes the second substrate 105B on the second ESC 310b over the rotation arm 313. For example, the first substrate 105A is immobilized on the first ESC 310a and the second substrate 105B is immobilized on the second ESC 310b. As described above, the topsides 105A-1, 105B-1 of the first and second substrates 105A, 105B, respectively, have been cleaned, activated, and aligned for bonding. However, the factory robot disposes the first and second substrates 105A, 105B within the processing region 303 such that the topsides 105A-1, 105B-1 are not capable of interfacing with one another in order to bond the first and second substrates 105A, 105B because the topsides 105A-1, 105B-1 are both oriented in the same direction within the processing region 303.

At operation 612, the second substrate 105B is rotated by 180 degrees about a first direction (e.g., X-direction) within a processing chamber by a rotation system of the bonding module. In some embodiments, the rotation system 312 is coupled to the rotation arm 313 and the second ESC 310b. With reference to FIG. 3B, the CPU 114 of the system controller 112 executes instructions that cause the CPU 114 to control the rotation system 312 and rotate the rotation arm 313 in a rotational direction 328 by about 180 degrees within the processing region 303. After the rotation of the rotation arm 313 in the rotational direction 328 within the processing region 303, the topside 105B-1 of the second substrate 105B is oriented in a direction that is opposite to the direction in which the topside 105A-1 of the first substrate 105A is oriented. Accordingly, the topsides 105A-1, 105B-1 are facing one another such that the first and second substrates 105A, 105B can be bonded to form the single composite structure.

Referring to FIGS. 3C, 4B, and 5A, with the topsides 105A-1, 105B-1 oriented to face one another and with the bottom sides 105A-2, 105B-2 immobilized on the first and second ESCs 310a, 310b, respectively, the system controller 112 begins actuating the second substrate 105B towards the first substrate 105A in order to bond the topside 105B-1 to the topside 105A-1. In some embodiments, the system controller 112 controls the actuator 305 to actuate the rotation arm 313 in the negative Z-direction such that the second ESC 310b is actuated towards the first ESC 310a within the processing region 303 of the processing chamber 306. Although the rotation arm 313 is described and illustrated as causing the actuation of the second substrate 105B towards the first substrate 105A, it is to be appreciated that, in various embodiments, the second substrate 105B can be actuated towards the first substrate 105A using other techniques. In one or more embodiments, the segments 411 of the second ESC 310b may be actuated by corresponding actuators 480 in order to actuate the second substrate 105B towards the first substrate 105A. Regardless of how this actuation is accomplished, the actuation of the second substrate 105B towards the first substrate 105A is ceased/halted when the second and first substrates 105B, 105A are separated by a relatively small distance such as a distance in a range of about 0.5 to 30 millimeters.

### Bonding Step Examples of One Bowed Substrate

At operation 614, at least one of the second substrate or the first substrate is bowed using electrostatic chucks (ESCs) of the bonding module. In some embodiments, the first and second ESCs 310a, 310b are utilized to bow at least one of the first substrate 105A or the second substrate 105B as part of operations within the bonding module 190. In the example shown in FIG. 5B, the second substrate 105B is bowed to have a convex curvature relative to the first substrate 105A. In order to bow the second substrate 105B as shown, the system controller 112 generally causes performance of operations including: (1) chucking the outer perimeter of the second substrate 105B to the second ESC 310b; (2) halting any forces urging the center of the second substrate 105B towards the second ESC 310b; and (3) applying one or more forces to the center of the second substrate 105B to extend the center of the second substrate 105B a distance away from the second ESC 310b.

In order to chuck the outer perimeter of the second substrate 105B to the second ESC 310b, the system controller 112 causes the second voltage source 326b to apply DC biases between pairs of electrodes disposed within segments 411 of the second ESC 310b that are disposed below a lateral portion (e.g., an edge portion) of the second substrate 105B. In an example in which the segments 411 of the second ESC 310b are oriented in a manner similar to the segments 411 illustrated in the plan view 402 of FIG. 4C, the system controller 112 causes the second voltage source 326b to apply the DC biases between pairs of electrodes disposed within each of the 16 outermost segments 411 which are disposed below the lateral portion of the second substrate 105B. The applied DC biases generate corresponding electrostatic forces which urge the lateral portion of the second substrate 105B towards the pairs of electrodes within the segments 411 that are disposed below the lateral portion of the second substrate 105B. Additionally or alternatively, the system controller 112 may cause the vacuum source 471 to apply a vacuum pressure to the second substrate 105B via one or more vacuum chucking ports 412 disposed below the lateral portion of the second substrate 105B. In some embodiments, the vacuum pressure urges the lateral portion of the second substrate 105B towards the one or more vacuum chucking ports 412 which can immobilize the lateral portion of the second substrate 105B on the second ESC 310b.

Continuing the above example, in order to halt any electrostatic forces urging the center of the second substrate 105B towards the second ESC 310b, the system controller 112 also ensures that DC biases are not applied between pairs of electrodes within segments 411 of the second ESC 310b that are disposed below a medial portion (e.g., a central portion) of the second substrate 105B. In the example of FIG. 4C, if the second voltage source 326b is applying DC biases to pairs of electrodes within the central segment 411 or within the four segments 411 surrounding the central segment 411, then the system controller 112 causes the second voltage source 326b to halt the application of these DC biases. By ensuring the DC biases are not applied between pairs of electrodes within segments 411 that are disposed below the medial portion of the second substrate 105B, the system controller 112 prevents electrostatic forces from urging the medial portion of the second substrate 105B towards surfaces of the segments 411 which would prevent the second substrate 105B from being bowed. Additionally, if the vacuum source 471 is applying a vacuum pressure to the medial portion of the second substrate 105B via one or more vacuum chucking ports 412 disposed below the second substrate 105B, then the system controller 112 also halts application of this vacuum pressure.

In order to apply the forces to the center of the second substrate 105B that cause the center of the second substrate 105B to extend the distance away from the second ESC 310b, the system controller 112 actuates one or more segments 411 (by controlling corresponding actuators 480) that are below the medial portion of the second substrate 105B. The system controller 112 actuates the segments 411 disposed below the second substrate 105B towards the first substrate 105A. The actuation causes the segments 411 to apply forces to the medial portion of the bottom side 105B-2 of the second substrate 105B. The applied forces to the medial portion of the second substrate 105B extend medial portion the distance away from the second ESC 310b causing the second substrate 105B to be bowed.

Additionally or alternatively, the system controller 112 can bow the second substrate 105B by delivering pressurized gas via one or more backside gas delivery ports (not shown) from the gas delivery system 472. The pressurized gas applies a force to the medial portion of the bottom side 105B-2 of the second substrate 105B which causes the second substrate 105B to be bowed. Additional forces can be applied to the bottom side 105B-2 by delivering one or more gases to the regions 431 (e.g., via the one or more backside gas delivery ports) in order to pressurize the regions 431 below the segments 441. As described above, pressurizing the regions 431 extends the membrane 428 relative to the supporting structure 429. Since, in some embodiments, the membrane 428 is continuous across the bottom sides of the segments 411, extending the membrane 328 applies forces to the bottom side 105B-2 of the second substrate 105B more uniformly than the forces that are applied to the bottom side 105B-2 by the segments 411. Application of these uniform forces facilitates improved control over a radius of the curvature in the bow of the second substrate 105B as the second substrate 105B is being bowed. In some examples, the system controller 112 causes the gas delivery system 472 to deliver a gas such as helium via the backside gas delivery ports to bow the second substrate 105B and/or to improve heat transfer during the bowing/bonding process.

In some examples, when the second substrate 105B is bowed, the bottom side 105B-2 of the second substrate 105B extends a distance from a surface of one or more segments 411 of the second ESC 310b in a range of about 0.2 to 1.0 millimeters. In one or more embodiments, the system controller 112 causes the distance between the surface of the one or more segments 411 and the medial portion of the bottom side 105B-2 to be measured using the capacitive sensors, using the mechanical displacements of one or more actuators 480, using the optical inspection system 200, and/or using another measurement system. Similarly, the system controller 112 may cause the convex curvature of the second substrate 105B to be measured to ensure that the curvature matches a desired curvature.

At operation 616, the second substrate is actuated towards the first substrate using the ESCs of the bonding module. With reference to FIG. 5C, the system controller 112 controls the actuator 305 to actuate the rotation arm 313 in the negative Z-direction such that the second ESC 310b is actuated further towards the first ESC 310a. Because the second substrate 105B is bowed, the medial portion of the topside 105B-1 of the second substrate 105B contacts a medial portion of the topside 105A-1 of the first substrate 105A before the lateral portion of the topside 105B-1 contacts a lateral portion of the topside 105A-1. In some embodiments, bowing the second substrate 105B minimizes stresses induced in the second substrate 105B during the process of bonding the first and second substrates 105A, 105B. In one or more embodiments, the vacuum environment may be configured to further minimize stresses induced in the second substrate 105B when bonding the second substrate 105B to the first substrate 105A.

With reference to FIG. 4B, the system controller 112 may manipulate the pixelated temperature controls in order to change the local temperatures within the pixelated temperature zones. By changing the temperature locally in each of the pixelated temperature zones, the system controller 112 may improve an accuracy of overlaying the first and second substrates 105A, 105B. In some embodiments, the system controller 112 computes offsets between the pixelated temperature zones, allows the local temperatures to stabilize, measures the stabilized local temperatures, and adjusts the stabilized local temperatures according to measured stabilized local temperatures and the computed offsets between the pixelated temperature zones.

At operation 618, the second substrate is bonded to the first substrate using the ESCs of the bonding module. With reference to FIGS. 5D and 5E, after the medial portion of the topside 105B-1 of the second substrate 105B contacts a medial portion of the topside 105A-1 of the first substrate 105A, the system controller 112 continues to control the actuator 305 to actuate the rotation arm 313 in the negative Z-direction. In some embodiments, as the bowed second substrate 105B is actuated towards the first substrate 105A, a force utilized to bow the second substrate 105B can be gradually reduced as an amount of a surface area in contact between the topsides 105B-1, 105A-1 increases. In one or more examples, gradually reducing the force utilized to bow the second substrate 105B may allow greater controllability of one or more characteristics of a bonding wave as the topsides 105B-1, 105A-1 contact one another. As shown in FIG. 5D, as a result of the continued actuation of the rotation arm 313 in the negative Z-direction, the lateral portion of the topside 105B-1 of the second substrate 105B contacts the lateral portion of the topside 105A-1 of the first substrate 105A which bonds the first and second substrates 105A, 105B as a single composite structure. Although the force utilized to bow the second substrate 105B is described as being gradually reduced, in some embodiments, when the lateral portion of the topside 105B-1 of the second substrate 105B contacts the lateral portion of the topside 105A-1 of the first substrate 105A, a force applied to the bottom side 105B-2 may be increased in order to bond the first and second substrates 105A, 105B as a single composite structure. In certain embodiments, the force applied to the bottom side 105B-2 for bonding the first and second substrates 105A, 105B may have a greater magnitude than the force utilized to bow the second substrate 105B.

As shown in FIG. 5E, after bonding the first and second substrates 105A, 105B, the system controller 112 causes the second voltage source 326b to halt the application of the DC biases to pairs of electrodes within the segments 411 of the second ESC 310b disposed below the lateral portion of the second substrate 105B. The system controller 112 then controls the actuator 305 to actuate the rotation arm 313 in the positive Z-direction which retracts the second ESC 310b relative to the second substrate 105B. Notably, by utilizing the first and second ESCs 310a, 310b to bond the first and second substrates 105A, 105B, the disadvantages of conventional bonding techniques such as thermal compression or use of adhesives are avoided. Additionally, use of the first and second ESCs 310a, 310b to bond the first and second substrates 105A, 105B enables the bonding of the first and second substrates 105A, 105B in low-pressure environments such as vacuum environments which improves controllability of the topsides 105A-1, 105B-1 as bonding surfaces. Unlike conventional bonding techniques, the first and second ESCs 310a, 310b are capable of selectively releasing portions of the first and second substrates 105A, 105B during the bonding process with relatively fast release response times. The ability to select and rapidly release portions of the first and second substrates 105A, 105B facilitates effective manipulation/control of bonding wave propagation uniformity which can further reduce bonding induced stresses and pattern distortion. In some embodiments, one or more segments 411 of the second ESC 310b can provide flexibility in scenarios in which different types of wafers/substrates require different bonding waves for maximum yield.

### Bonding Step Examples of Two Bowed Substrates

Returning to operation 614, in the example described above, the second substrate 105B is bowed while the first substrate 105A remains flat as part of bonding the first and second substrates 105A, 105B. Bowing the second substrate 105B can minimize stresses induced in the second substrate 105B during the bonding process within the bonding module 190. However, in some embodiments, as shown in FIGS. 5F-5G, the second substrate 105B is bowed and the first substrate 105A is also bowed in order to minimize stresses induced in the first substrate 105A during the bonding process. In one or more embodiments, the second substrate 105B is bowed as described in the example above and the first substrate 105A is bowed in a same or similar manner as the second substrate 105B.

With reference to FIG. 5F, the second substrate 105B is bowed to have the convex curvature relative to the first substrate 105A a convex curvature relative to the first substrate 105A, and the first substrate 105A is bowed to have a convex curvature relative to the second substrate 105B. Returning to operation 616 and with reference to FIG. 5G, the system controller 112 controls the actuator 305 to actuate the rotation arm 313 in the negative Z-direction such that the second ESC 310b is actuated towards the first ESC 310a. As shown, an actuation of the second ESC 310b towards the first ESC 310a actuates the topside 105B-1 of the second substrate 105B towards the topside 105A-1 of the first substrate 105A. Because both the second and first substrates 105B, 105A are bowed, medial portions of the topsides 105B-1, 105A-1 contact one another before lateral portions of the topsides 105B-1, 105A-1 contact one another.

Returning to operation 618 and with reference to FIG. 5D, after the medial portions of the topsides 105B-1, 105A-1 contact, the system controller 112 continues to control the actuator 305 to further actuate the rotation arm 313 in the negative Z-direction. This further actuation causes the lateral portions of the topsides 105B-1, 105A-1 of the second and first substrates 105B, 105A, respectively, to contact one another. With reference to FIG. 5E, after the lateral portions of the topsides 105B-1, 105A-1 have contacted, the second substrate 105B is bonded to the first substrate 105A and the system controller 112 actuates the rotation arm 313 in the positive Z-direction. Actuating the rotation arm 313 in the positive Z-direction retracts the second ESC 310b from the second substrate 105B which is now bonded to the first substrate 105A.

Although bowing both the first and second substrates 105A, 105B is described as minimizing stresses induced in the first and second substrates 105A, 105B during the bonding process, it is to be appreciated that, in some examples, bowing both the first and second substrates 105A, 105B is advantageous for reasons in addition to minimizing induced stresses. In one example, bowing both the first and second substrates 105A, 105B may provide greater controllability of the bonding wave generated as the first and second substrates 105A, 105B are bonded. In another example, bowing both the first and second substrates 105A, 105B may produce stronger bonds as relatively small surface areas of the first and second substrates 105A, 105B can be bonded locally without being impacted by one or more surface imperfections outside of the relatively small surface areas.

Bonding the first and second substrates 105A, 105B using the first and second ESCs 310a, 310b avoids the disadvantages associated with conventional bonding techniques such as use of adhesives or thermal compression. Moreover, utilizing the first and second ESCs 310a, 310b for substrate bonding facilitates bonding over a wide range of pressures including very low pressures which increases control over surface-to-surface bonding. Since first and second ESCs 310a, 310b are capable of precisely shaping substrates, the described systems are able to bond substrates that are initially not flat and may have convex/concave curvatures or have “saddle” shapes. Additionally, after bonding the first and second substrates 105A, 105B using the first and second ESCs 310a, 310b, if an inspection of the bonded first and second substrates 105A, 105B indicates that these substrates are misaligned, then the first and second substrates 105A, 105B can be separated and bonded again to correct the misalignment.

### Additional Considerations

In the above description, details are set forth by way of example to facilitate an understanding of the disclosed subject matter. It should be apparent to a person of ordinary skill in the field, however, that the disclosed implementations are exemplary and not exhaustive of all possible implementations. Thus, it should be understood that reference to the described examples is not intended to limit the scope of the disclosure. Any alterations and further modifications to the described devices, instruments, methods, and any further application of the principles of the present disclosure are fully contemplated as would normally occur to one skilled in the art to which the disclosure relates. In particular, it is fully contemplated that the features, components, and/or steps described with respect to one implementation may be combined with the features, components, and/or steps described with respect to other implementations of the present disclosure. As used herein, the term “about” may refer to a +/−10% variation from the nominal value. It is to be understood that such a variation can be included in any value provided herein.

As used herein, “a processor,” “at least one processor” or “one or more processors” generally refers to a single processor configured to perform one or multiple operations or multiple processors configured to collectively perform one or more operations. In the case of multiple processors, performance of the one or more operations could be divided amongst different processors, though one processor may perform multiple operations, and multiple processors could collectively perform a single operation. Similarly, “a memory,” “at least one memory” or “one or more memories” generally refers to a single memory configured to store data and/or instructions, multiple memories configured to collectively store data and/or instructions.

As used herein, a phrase referring to “at least one of” a list of items refers to any combination of those items, including single members. As an example, “at least one of: a, b, or c” is intended to cover: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

The methods disclosed herein comprise one or more steps or actions for achieving the described method. The method steps and/or actions may be interchanged with one another without departing from the scope of the claims. In other words, unless a specific order of steps or actions is specified, the order and/or use of specific steps and/or actions may be modified without departing from the scope of the claims.

While the foregoing is directed to embodiments of the present disclosure, other and further embodiments of the disclosure may be devised without departing from the basic scope thereof, and the scope thereof is determined by the claims that follow.

We claim:

1. An apparatus comprising:
a first electrostatic chuck (ESC) comprising one or more segments, wherein the first ESC is disposed within a processing region of a processing chamber and a surface of each of the one or more segments of the first ESC defines a first chucking surface that is oriented in a first direction, wherein each of the one or more segments of the first ESC comprise at least one first electrode, and the at least one first electrode in each of the one or more segments of the first ESC is configured to receive a first DC bias configured to generate a first chucking force that causes a first substrate to be urged against the first chucking surface;
a second ESC comprising one or more segments, wherein the second ESC is disposed within the processing region of the processing chamber and a surface of each of the one or more segments of the second ESC defines a second chucking surface that is oriented in a second direction that is opposite the first direction, wherein each of the one or more segments of the second ESC comprise at least one second electrode, and the at least one second electrode in each of the one or more segments of the second ESC is configured to receive a second DC bias configured to generate a second chucking force that causes a second substrate to be urged against the second chucking surface; and
an actuator configured to position the first ESC relative to the second ESC.

2. The apparatus of claim 1, wherein the first substrate is bowed and a medial portion of the first substrate contacts the second substrate before a lateral portion of the first substrate contacts the second substrate.

3. The apparatus of claim 2, wherein the actuator actuates the first ESC based on a curvature of the first substrate.

4. The apparatus of claim 1, wherein the first substrate and the second substrate are aligned before the actuator positions the first ESC relative to the second ESC.

5. The apparatus of claim 4, wherein the first substrate is rotated 180 degrees before the actuator positions the first ESC relative to the second ESC.

6. The apparatus of claim 1, wherein the second substrate is bowed and a medial portion of the first substrate contacts a medial portion of the second substrate before a lateral portion of the first substrate contacts a lateral portion of the second substrate.

7. The apparatus of claim 1, wherein the actuator is included in a rotation system that rotates the first ESC within the processing region.

8. The apparatus of claim 1, further comprising:
a first segment and a second segment of the one or more segments of the first ESC; and
an additional actuator configured to actuate the first segment relative to the second segment.

9. The apparatus of claim 1, further comprising at least one pair of electrodes in each of the one or more segments of the first ESC wherein the at least one pair of electrodes is configured to receive the first DC bias and includes the at least one first electrode.

10. The apparatus of claim 1, wherein the first ESC includes a port configured to deliver pressurized gas that causes the first substrate to bow.

11. A method comprising:
chucking a first substrate to a first surface of a first electrostatic chuck (ESC) disposed within a processing chamber, the first surface oriented in a first direction within a processing region of the processing chamber;
chucking a second substrate to a second surface of a second ESC disposed within the processing chamber, the second surface oriented in a second direction within the processing region that is opposite the first direction;
actuating the second substrate towards the first substrate; and
bonding the second substrate to the first substrate.

12. The method of claim 11, further comprising:
bowing the second substrate;
contacting the first substrate with a medial portion of the second substrate before contacting the first substrate with a lateral portion of the second substrate; and
contacting the first substrate with the lateral portion of the second substrate.

13. The method of claim 11, further comprising:
actuating a segment of the second ESC in the second direction; and
bowing the second substrate based on actuating the segment in the second direction.

14. The method of claim 11, wherein the first substrate and the second substrate are aligned before actuating the second substrate towards the first substrate.

15. The method of claim 11, wherein at least one of the first substrate or the second substrate is rotated 180 degrees within the processing region.

16. The method of claim 11, further comprising:
bowing the first substrate by actuating at least one segment of the first ESC; and
bowing the second substrate by actuating at least one segment of the second ESC.

17. A method comprising:
receiving a first DC bias by at least one first electrode of a first electrostatic chuck (ESC) disposed within in a processing chamber;
immobilizing a first substrate on a surface of the first ESC based on the first DC bias;
receiving a second DC bias by at least one second electrode of a second ESC disposed within the processing chamber;
immobilizing a second substrate on a surface of the second ESC based on the second DC bias; and
rotating the second substrate and the second ESC so that the first substrate faces the second substrate.

18. The method of claim 17, further comprising:
actuating the second substrate towards the first substrate within the processing chamber; and
contacting the first substrate with a medial portion of the second substrate before contacting the first substrate with a lateral portion of the second substrate.

19. The method of claim 18, further comprising bonding the second substrate to the first substrate within the processing chamber.

20. The method of claim 17, further comprising:
aligning the first substrate and the second substrate; and
bowing the second substrate.
